(19) United States
(12) Patent Application Publication
(10) Pub. No.: US 2025/0267810 A1
(43) Pub. Date: Aug. 21, 2025

(54) ASSEMBLIES FOR MOUNTING ANTENNA CABLES

(71) Applicant: Outdoor Wireless Networks LLC, Claremont, NC (US)

(72) Inventors: Marcus J. Ash, Castle Rock, CO (US); Serge S. Honeysett, Clay, NY (US); Bin Ai, Suzhou (CN); Jian Xu, Suzhou (CN)

(21) Appl. No.: 19/024,151

(22) Filed: Jan. 16, 2025

Related U.S. Application Data
(60) Provisional application No. 63/644,679, filed on May 9, 2024.
(60) Provisional application No. 63/553,767, filed on Feb. 15, 2024.

(51) Int. Cl. H05K 5/02; H01Q 1/12

(52) U.S. Cl. CPC H05K 5/0247; H05K 5/0217; H01Q 1/1228

(57) ABSTRACT

The present application is directed to an assembly for providing mounting locations for cable hangers for an antenna. The assembly includes a hanger panel having a generally rectangular skeletal base. The hanger panel includes a plurality of mounting holes spaced apart on opposing side surfaces along a length of the base and at least one securing mechanism coupled to and extending outwardly from an end of the base. The assembly further includes an adapter extension having a side wall comprising a recess. The hanger panel is secured to the side wall of the adapter extension by the at least one securing mechanism received within the recess.

### RELATED APPLICATIONS

The present application claims priority to and the benefit of U.S. Provisional Patent Application No. 63/553,767, filed Feb. 15, 2024, and U.S. Provisional Patent Application No. 63/644,679, filed May 9, 2024, the contents of which are hereby incorporated by reference in full.

### FIELD

The present invention relates generally to mounts for antennas, radios and cables, and more particularly to mounts for antennas, radios and cables on an antenna tower or monopole.

### BACKGROUND

With increased demand for more wireless communication, the number of radio and antenna units that a tower traditionally supports has increased and is expected to continue to increase. New towers will need to be designed to support greater numbers of antenna and radio units, while existing towers are retrofitted to support more units, and effort is made to fully utilize space available on the towers.

Antennas typically mount to a round pipe; an exemplary mount with round vertical pipes for antenna mounting is shown in U.S. Pat. No. 9,812,762 to Skrepcinski, the disclosure of which is hereby incorporated herein in its entirety). When mounting antennas to towers or other structures, the cables attaching the radio to the antenna typically protrude from the bottom of the antenna for some unsupported length. It is typically desirable to secure these cables to maintain a sense of organization and to prevent swaying in the wind. A system of cable support brackets is commonly used to hold these cables in place. Those cable support systems usually also mount to the same pipe to which the antenna is mounted, and include two half-clamps that are joined with bolts that extend on either side of the pipe. The front plane of one of the half-clamps is parallel to the face of the antenna. Additional brackets are then bolted onto the front half-clamp. Additional support may be needed behind the antenna when the radio is not mounted in close proximity to the antenna and from the radio to an overvoltage protection unit, which is typically mounted in a central position on the mount to feed up to 6 radios.

Areas near cellular antennas (i.e., within 1λ, or one wavelength) can be (relatively) high radio frequency (RF) energy environments. Conductive items in these areas, such as hangers, brackets and other hardware, can generate undesirable passive intermodulation (PIM). Typical examples of potential PIM-generating conditions include the combination of steel-on-steel contact (between two or more components), plus low contact pressure and/or relative movement between the steel components at the joint. As such, it may be desirable to provide solutions for hanging cables with reduced (or eliminated) likelihood of PIM generation.

One approach is offered in U.S. Pat. No. 11,159,006 to Heath et al., the disclosure of which is hereby incorporated herein by reference in full. The approach discussed therein features an assembly that includes: a pair of L-shaped members, each of the L-shaped members including a main panel, a pair of jaws extending from opposite edges of the main panel, and a flange extending generally perpendicularly to the main panel. The main panel includes a plurality of first mounting apertures and the flange includes a plurality of second mounting apertures. Each of a pair of rods extends through a first mounting aperture of each of the L-shaped members; and a securing component that engages each rod to fix the members relative to each other so that the jaws are mounted to a mounting pole. Cable hangers can then be mounted in the second mounting apertures on the flange to provide organization for cables connecting an antenna mounted on the mounting pole. This is a popular solution, but it may be desirable to provide additional solutions that can increase flexibility and/or reduce PIM.

### SUMMARY

As a first aspect, embodiments of the invention are directed to an assembly for providing mounting locations for cable hangers for an antenna. The assembly includes a hanger panel having a generally rectangular skeletal base. The hanger panel includes a plurality of mounting holes spaced apart on opposing side surfaces along a length of the base and at least one securing mechanism coupled to and extending outwardly from an end of the base. The assembly further includes an adapter extension having a side wall comprising a recess. The hanger panel is secured to the side wall of the adapter extension by the at least one securing mechanism received within the recess.

As a second aspect, embodiments of the invention are directed to a cable hanger assembly. The assembly includes a generally rectangular skeletal base having a length and a width, a plurality of mounting holes spaced apart on opposing side surfaces along the length of the base, a latch coupled to and extending outwardly from an end of the base, and a pair of hooks extending outwardly from the end of the base above the latch. The cable hanger assembly is formed of a polymeric material.

As a third aspect, embodiments of the invention are directed to a cable mounting kit. The kit includes first and second clamps. The first clamp including a first securing feature configured to engage a second securing feature on the second clamp to enable the first and second clamps to enclose and mount on a mounting structure, each of the first and second clamps including a clamping surface configured to engage the mounting structure and an opposed outer surface with a pair of first mounting openings. The kit further includes a cable hanger mounting assembly. The cable hanger mounting assembly includes a hanger panel having a generally rectangular skeletal base, the hanger panel having a plurality of mounting holes spaced apart on opposing side surfaces along a length of the base and at least one securing mechanism coupled to and extending outwardly from an end of the base. The cable hanger mounting assembly further includes an adapter extension having a first side wall having a recess and a second side wall having a pair of latches. The at least one securing mechanism of the hanger panel is configured to be received within the recess of the adapter extension, and the pair of latches of the adapter extension is configured to be received by the pair of first mounting openings of the first and second clamps.

It is noted that aspects of the invention described with respect to one embodiment, may be incorporated in a different embodiment although not specifically described relative thereto. That is, all embodiments and/or features of any embodiment can be combined in any way and/or combination. Applicant reserves the right to change any originally filed claim and/or file any new claim, accordingly, including the right to be able to amend any originally filed claim to depend from and/or incorporate any feature of any other claim or claims although not originally claimed in that manner. These and other objects and/or aspects of the present invention are explained in detail in the specification set forth below. Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

FIG. 1 is a perspective view of an assembly according to embodiments of the invention mounted on a mounting pole.

FIG. 2 is a perspective view of one of the clamps of the assembly of FIG. 1.

FIG. 3 is a perspective view of one of the adapter extensions of the assembly of FIG. 1.

FIG. 4 is a perspective view of one of the hanger panels of the assembly of FIG. 1.

FIG. 5 is a perspective view of the clamps of the assembly of FIG. 1 mounted on the mounting pole.

FIGS. 6-9 are perspective views of different configurations the components of the assembly of FIG. 1 may take. FIG. 6 shows one hanger panel of FIG. 4 mounted directly to one of the clamps, FIG. 7 shows one hanger panel of FIG. 4 mounted to a clamp via an adapter extension of FIG. 3, FIG. 8 shows two hanger panels of FIG. 4 mounted directly to the clamps, and FIG. 9 shows two hanger panels of FIG. 4 mounted to the clamps via adapter extensions of FIG. 3.

FIGS. 10-12 are perspective views of the assemblies of FIGS. 5, 7 and 9 with cable hangers mounted thereon.

FIGS. 13A-13C are top, front and perspective views of the clamp of FIG. 2.

FIG. 14 is a perspective view of two clamps of FIGS. 13A-13C illustrating how the clamps are secured together.

FIG. 15 is a perspective view of an assembly according to alternative embodiments of the invention.

FIGS. 16A-16D are perspective views of one of the clamps of the assembly of FIG. 15.

FIG. 17 is a clamp pin used to secure the clamp members of the assembly of FIG. 15.

FIG. 18 is an eye bolt used to secure the clamp members of the assembly of FIG. 15.

FIG. 19 is a perspective view of the assembly of FIG. 15 showing how the clamp pin and eyebolt are employed to secure the clamps of FIG. 15.

FIG. 20 is a perspective view of an assembly according to further embodiments of the invention.

FIGS. 21A-21D are perspective views of one of the clamps of the assembly of FIG. 20.

FIGS. 22A-22C are perspective views of a latch lever, a latch link, and a latch pin used to secure the assembly of FIG. 20.

FIG. 23 is a perspective view of the assembly of FIG. 20 showing how the components of FIGS. 22A-22C are employed to secure the clamps of FIG. 20.

FIG. 24 is a front perspective view of a clamp of an assembly (shown in FIG. 32) for mounting cables according to further embodiments of the invention.

FIG. 25 is a rear perspective view of the clamp of FIG. 24.

FIG. 26 is a front perspective view of an adapter extension of the assembly of FIG. 32.

FIG. 27 is a rear perspective view of the adapter extension of FIG. 26.

FIG. 28 is a rear perspective view of a hanger panel of the assembly of FIG. 32.

FIG. 29 is a front perspective view of the hanger panel of FIG. 28.

FIG. 30 is a rear perspective view of a mounting adapter of the assembly of FIG. 32.

FIG. 31 is a front perspective view of the mounting adapter of FIG. 24.

FIG. 32 is an exploded view of an assembly for mounting cables according to further embodiments of the invention.

FIG. 33A is a front perspective view of a T-shaped opening in the clamp of FIG. 24.

FIG. 33B is a rear perspective view of a T-shaped latch of the adapter extension of FIG. 26.

FIGS. 33C-33E are sequential section views showing the insertion of the latch of FIG. 33B into the opening of FIG. 33A.

FIG. 33F is a partial view showing the support member of the adapter extension of FIG. 26 engaging the clamp of FIG. 24.

FIG. 34 is a partially exploded view of two assemblies of FIG. 32 (without the mounting adapters) being brought together to mount on a mounting structure (such as a mounting pole).

FIG. 35 is a front perspective view of a mounting adapter according to additional embodiments of the invention.

FIG. 36 is a rear perspective view of the mounting adapter of FIG. 35.

FIG. 37 is a front perspective view of an adapter extension according to additional embodiments of the invention.

FIG. 38 is a rear perspective view of the adapter extension of FIG. 37.

FIG. 39 is a front perspective view of a hanger panel according to additional embodiments of the invention.

FIG. 40 is a rear perspective view of the hanger panel of FIG. 39.

FIG. 41 is an exploded perspective view of an assembly that includes a clamp, the mounting adapter of FIG. 35, the adapter extension of FIG. 37, and four of the hanger panels of FIG. 39.

FIG. 42 is a perspective view of the assembly of FIG. 41.

FIG. 43A is a perspective view of a hanger panel according to embodiments of the present invention.

FIG. 43B is a side view of the hanger panel of FIG. 43A.

FIG. 43C is a top view of the hanger panel of FIG. 43A.

FIG. 43D is an end view of the hanger panel of FIG. 43A.

FIG. 44A is a perspective view of another adapter extension according to embodiments of the present invention.

FIG. 44B is a rear view of the adapter extension of FIG. 44A.

FIG. 44C is a top view of the adapter extension of FIG. 44A.

FIG. 44D is a side view of the adapter extension of FIG. 44A.

FIG. 45A is an enlarged view of a securing mechanism of the adapter extension of FIG. 44A engaged with the adapter extension of FIG. 26 according to embodiments of the present invention.

FIG. 45B is an enlarged view of another securing mechanism of the adapter extension of FIG. 44A engaged with the hanger panel of FIG. 43A according to embodiments of the present invention.

FIG. 46A is a perspective view of an assembly according to embodiments of the present invention utilizing two hanger panels of FIG. 43A secured to the adapter extension of FIG. 44A.

FIG. 46B is a side view of the assembly of FIG. 46A.

FIG. 46C is a top view of the assembly of FIG. 46C.

FIG. 47 is a perspective view of an alternative assembly according to embodiments of the present invention utilizing one hanger panel of FIG. 43A and one adapter extension of FIG. 44A.

FIGS. 48A-48C are top views of different configurations of the assemblies of FIG. 46A and FIG. 47 used with the clamp of FIG. 24 (FIGS. 48A-48B) or the adapter extension of FIG. 26 (FIG. 48C).

FIGS. 49A-49H are perspective views of alternative configurations that assemblies according to embodiments of the present invention may take.

FIG. 50A is a front perspective view of an alternative clamp according to embodiments of the present invention.

FIG. 50B is a front view of the clamp of FIG. 50A.

FIG. 51A is a side view of an alternative adapter extension according to embodiments of the present invention.

FIG. 51B is a top view of the adapter extension of FIG. 51A.

FIG. 51C is an enlarged perspective view of a locking mechanism of the adapter extension of FIG. 51B according to embodiments of the present invention.

FIG. 51D is an enlarged perspective view of the anti-rotation feature of the adapter extension of FIG. 51B according to embodiments of the present invention.

FIG. 52 is a top perspective view of an alternative adapter extension of FIGS. 51A-51B according to embodiments of the present invention.

FIG. 53A is a front view of an alternative hanger panel according to embodiments of the present invention.

FIG. 53B is a top view of the hanger panel of FIG. 53A.

FIGS. 54A-54B illustrate different locking mechanisms for the components of the assemblies according to embodiments of the present invention.

FIG. 55A-55B illustrate an anti-rotation feature for assemblies according to embodiments of the present invention.

FIG. 56A is a top view of an assembly that may be used with a remote radio unit according to embodiments of the present invention.

FIG. 56B is a top perspective view of the assembly of FIG. 56A.

FIG. 57 is a perspective view of a stacked configuration of the assembly of FIG. 56B according to embodiments of the present invention.

FIGS. 58A-58B are side views of the assembly of FIG. 56A installed under remote radio units according to embodiments of the present invention.

FIGS. 59A-59B are perspective views of alternative assemblies that may be used with a remote radio unit according to embodiments of the present invention.

### DETAILED DESCRIPTION

The present invention is described with reference to the accompanying drawings, in which certain embodiments of the invention are shown. This invention may, however, be embodied in many different forms and should not be construed as limited to the embodiments that are pictured and described herein; rather, these embodiments are provided so that this disclosure will be thorough and complete, and will fully convey the scope of the invention to those skilled in the art. It will also be appreciated that the embodiments disclosed herein can be combined in any way and/or combination to provide many additional embodiments.

Unless otherwise defined, all technical and scientific terms that are used in this disclosure have the same meaning as commonly understood by one of ordinary skill in the art to which this invention belongs. The terminology used in the below description is for the purpose of describing particular embodiments only and is not intended to be limiting of the invention. As used in this disclosure, the singular forms “a”, “an” and “the” are intended to include the plural forms as well, unless the context clearly indicates otherwise. It will also be understood that when an element (e.g., a device, circuit, etc.) is referred to as being “connected” or “coupled” to another element, it can be directly connected or coupled to the other element or intervening elements may be present. In contrast, when an element is referred to as being “directly connected” or “directly coupled” to another element, there are no intervening elements present.

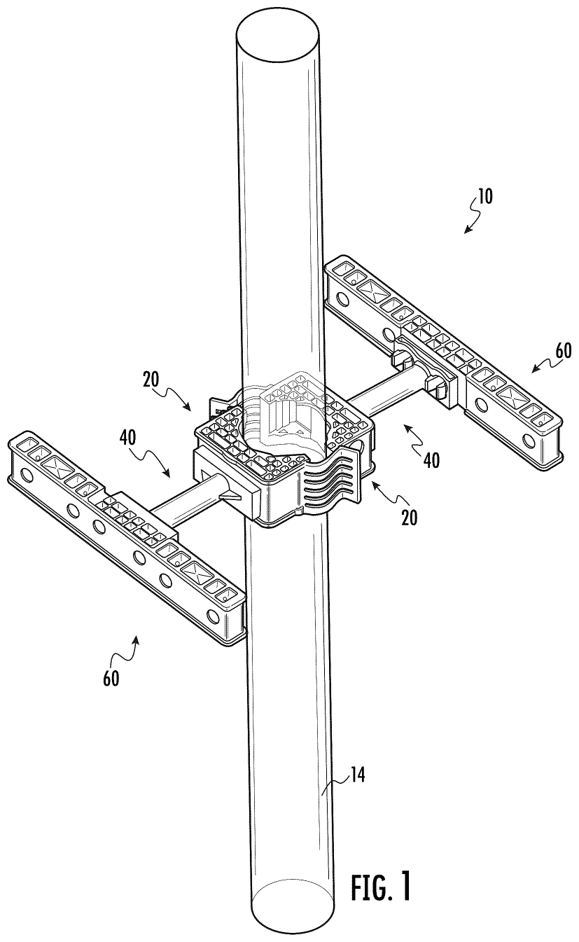

Referring now to the drawings, an assembly for mounting antenna cables is shown in FIG. 1 and designated broadly therein at 10. The assembly 10 includes two clamps 20, two adapter extensions 40, and two hanger panels 60, which are then mounted on a mounting pole 14. These components are described in greater detail below. See also U.S. Patent Application Publication No. 2024/0039264 to Wang et al., the disclosures of which are incorporated herein by reference in their entirety.

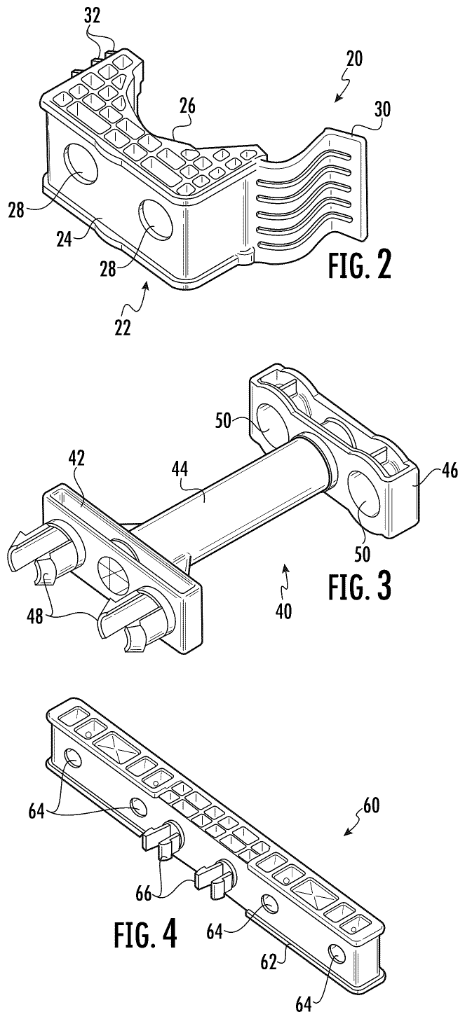

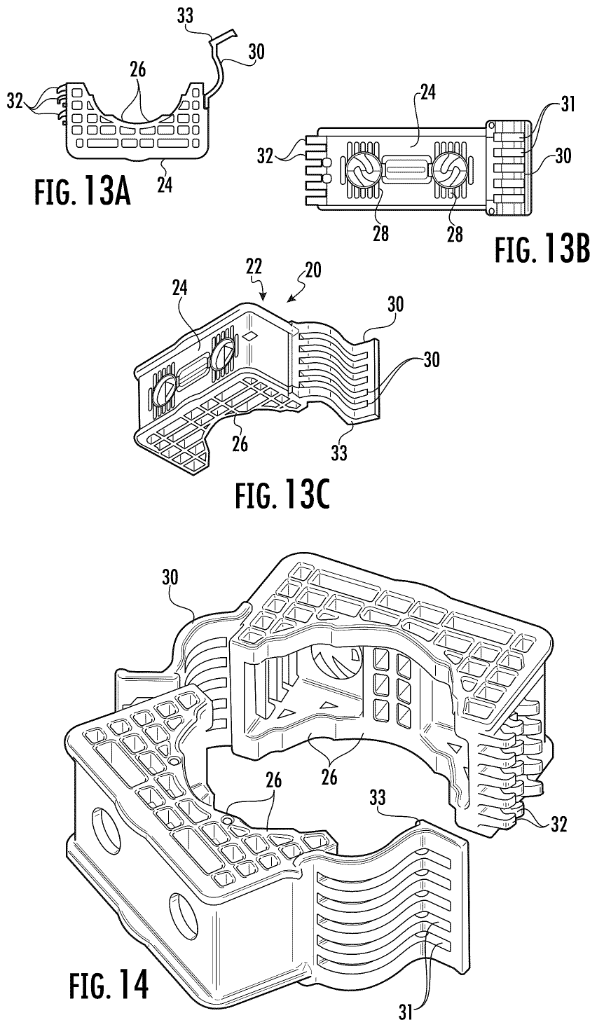

Referring now to FIG. 2, one of the clamps 20 is shown therein. The clamp 20 includes a skeletal body 22 with a generally flat outer surface 24 and arcuate clamping surfaces 26 opposite the outer surface 24. Two mounting holes 28 (typically with a ¾ inch nominal diameter) are located in the outer surface 24. A generally S-shaped latch 30 extends from one end of the body 22. A plurality of fingers 32 extend from the opposite end of the body 22 (see FIGS. 13A-13C). The latch 30 and fingers 32 are configured to secure two clamps 20 around a mounting pole 14; details regarding the latch 30 and fingers 32 and how they secure the clamps 20 are provided below in connection with the discussion of FIGS. 13A-13C and 14.

Referring now to FIG. 3, one of the adapter extensions 40 is shown therein. The adapter extension 40 includes a base 42, a shaft 44 that is fixed to the base 42 and extends generally normal thereto, and a head 46 that is fixed to the base and is generally parallel with the base 42. Two snap-fit latches 48 are mounted to the base 42 opposite the shaft 44, and are sized and positioned to fit within the mounting holes 28 of the clamp 20. Two mounting holes 50 are located in the head 46 and are sized and spaced similarly to the mounting holes 28.

Referring now to FIG. 4, the hanger panel 60 has a generally rectangular skeletal base 62. Four mounting holes 64 (typically having a nominal diameter of ¾ inch) are spaced across the front surface of the base 42. Two snap-fit latches 66 extend from the rear surface of the base 62; the latches 66 are sized and positioned to fit within the mounting holes 50 of the adapter extension 40 or the mounting holes 28 in the clamp 20.

In some embodiments, all of the clamps 20, adapter extensions 40 and hanger panels 60 comprise a polymeric material. When so formed, none of the joints or connections between these components includes a metal-to-metal contact surface, such that no PIM is generated at these joints/connections.

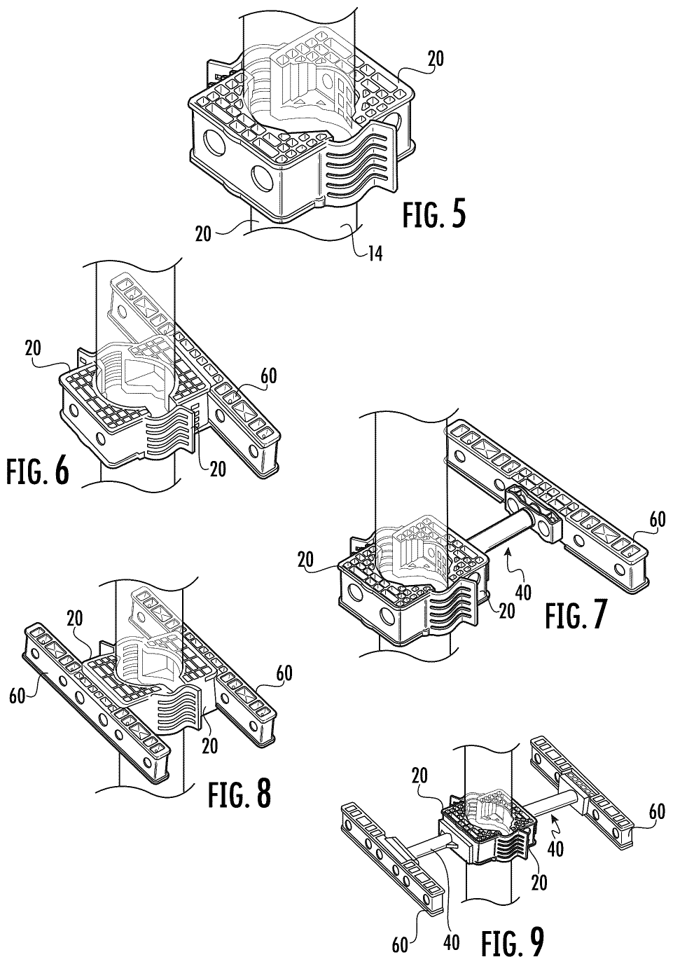

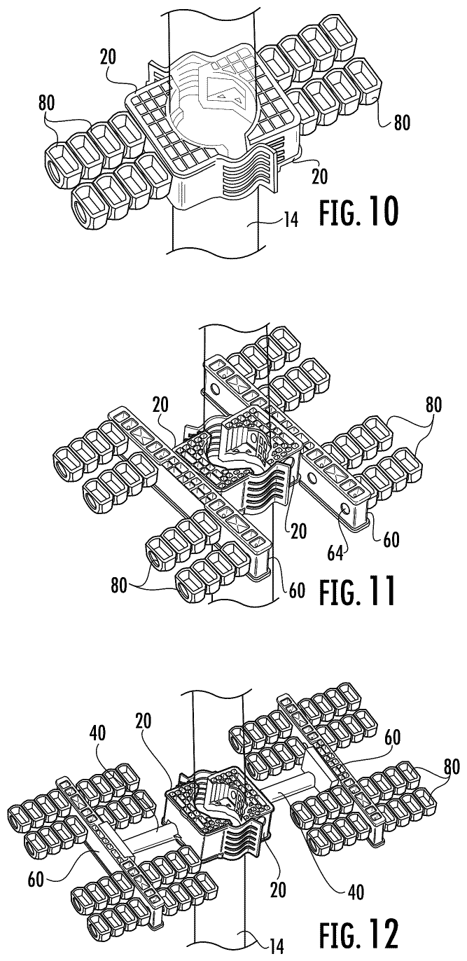

As can be seen in FIGS. 5-9, these components can be employed in various combinations to provide mounting locations for cable hangers, which are in turn used to grasp and assist in organizing cables near an antenna. FIG. 5 illustrates two clamps 20 fastened together and mounted on a mounting pole 14. In this configuration, cable hangers (shown in FIG. 10 at 80) are mounted in the mounting holes 28 in the clamps 20. Because the cable hangers 80 are stackable on each other, a large number of cables can be grasped and organized in a small area. Such stackable cable hangers are well-known in this field, and are described in, for example, U.S. Pat. No. 10,158,218 to Vaccaro et al.; U.S. Pat. No. 11,004,367 to Vaccaro et al.; and U.S. Pat. No. 10,801,646 to Vaccaro; and co-pending and co-assigned U.S. Patent Publication No. 2022/0316622 (U.S. patent application Ser. No. 17/577,570) to Joshi et al., each of which is incorporated herein by reference in full.

An alternative configuration is shown in FIG. 6, wherein one hanger panel 60 is mounted directly to one of the clamps 20 via the insertion of snap-fit latches 66 of the hanger panel 60 into mounting holes 28 of the clamp 20. FIG. 8 shows a configuration with two hanger panels 60, with one hanger panel 60 mounted to each of the clamps 20. FIG. 11 illustrates stacks of cable hangers 80 mounted in each of the mounting holes 64 of the hanger panels 60.

Another alternative configuration is shown in FIG. 7, wherein one adapter extension 40 is mounted via the snap-fit latches 48 in the mounting holes 28 of one of the clamps 20, and one hanger panel 60 is mounted via the snap-fit latches 66 in the mounting holes 50 of the adapter extension 50. FIG. 9 shows a configuration like that of FIG. 7, but with two sets of adapter extensions 40 and hanger panels 60 mounted to the clamps 20 (this arrangement is also shown in FIG. 1). FIG. 12 illustrates stacks of cable hangers 80 mounted in the mounting holes 64 of the hanger panels 60.

The configuration if FIGS. 9 and 12 can also provide an advantage when used to mount and organize fiber optic cable. Fiber optic cable typically has a minimum bend radius, which refers to a bend radius below which the cable should not be bent in order to avoid damage to the optical fibers. The length of the adapter extensions may be selected so that the hanger panels 60 are separated by a distance that enables fiber optic cables to be mounted thereon without reaching the minimum bend radius. As an example, the hanger panels 60 may be separated by at least 10 inches, and in some instance 12 inches or even 14 inches, to avoid minimum bend radius concerns.

Thus, it can be seen that the collection of clamps 20, adapter extensions 40 and hanger panels 60 can provide a technician with numerous ways to mount cable hangers 80, and can do so while eliminating PIM that might be generated by metal-on-metal contact surfaces.

As described above, the clamps 20 are configured so that they can be secured to each other in order to mount on a mounting pole 14. FIGS. 13A-13C illustrate one clamp 20 in more detail. As can be seen in these figures, the aforementioned latch 30 is generally S-shaped and includes five slots 31 along its length. A rib 33 extends across the width of the latch 30 on its inboard surface. On the opposite side of the body 22 of the clamp 20, the fingers 32 are arranged in three rows, with each row having five fingers 32. When two clamps 20 are brought together for securing to a mounting pole 14, the fingers 32 of one clamp 20 are received in the slots 31 in the latch 30 of the other clamp 20. The fingers 32 are hooked, such that they engage and capture the rib 33 of the latch 31. Because there are multiple rows of fingers 32 on each clamp 20, a technician can select the row of fingers 32 that enables the clamps 20 be securely fastened for the mounting pole 14 within a relatively broad range of diameters.

It can also be seen in FIGS. 13A and 14 that the clamping surfaces 26 of each clamp 20 are not smoothly continuous, but instead comprise multiple arced segments. The presence of these segments can enable the clamps 20 to be secured tightly to mounting poles 14 of different diameters.

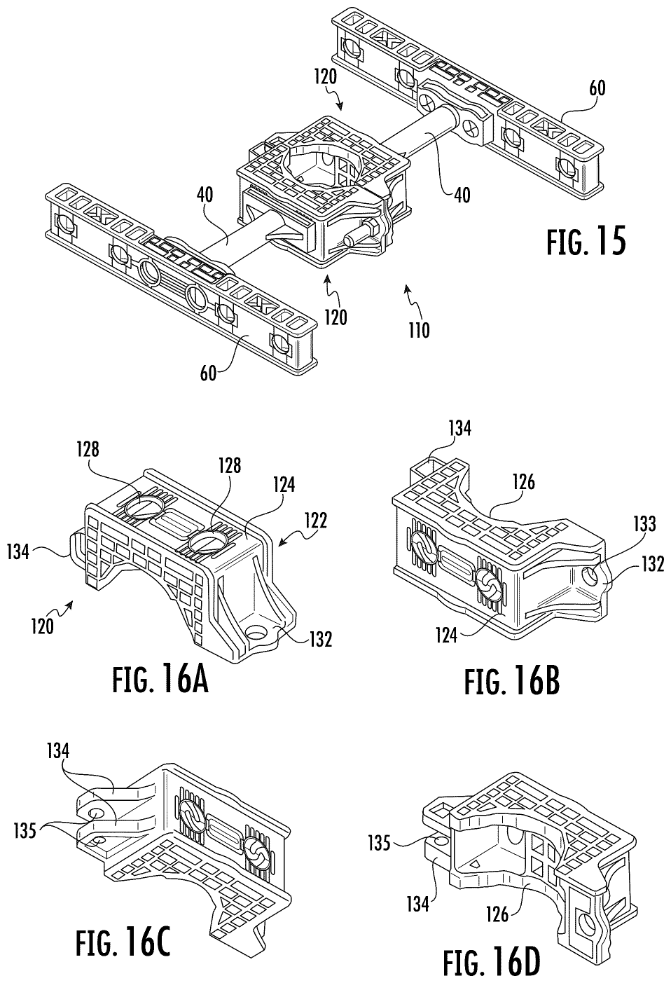

Referring now to FIGS. 15-19, another assembly, designated broadly at 110, is shown therein. The assembly 110 includes adapter extensions 40 and hanger panels 60 like those of the assembly 10, but utilizes clamps 120 that are configured to be secured together differently than the clamps 20. As shown in FIGS. 16A-16D, each clamp 120 has a body 122, an outer surface 124 with mounting holes 128, and clamp surfaces 126 like the clamp 20. However, on one side of the body 122 the clamp 120 has a platform 132 with a mounting hole 133, and on the opposite side of the body 122 the clamp 120 has two gussets 134 with mounting holes 135.

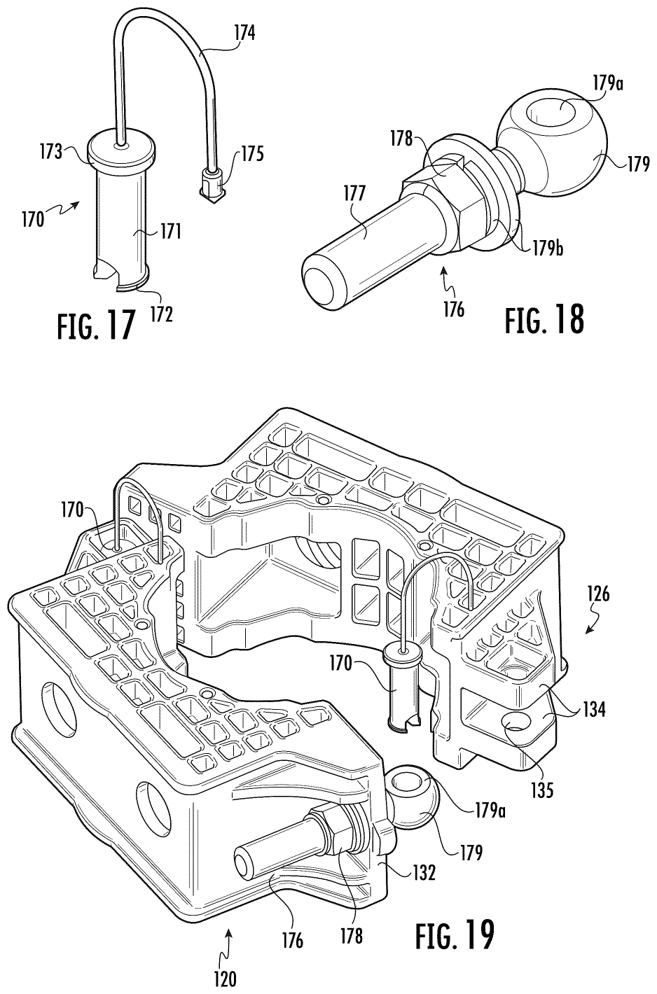

The clamps 120 are secured with a clamp pin 170 and an eye bolt 176. As shown in FIG. 17, a clamp pin 170 has a body 171 with hooks 172 at its lower end, a collar 173 at the upper end of the body 171, and a tether 174 that extends from the collar 173 and has a clip 175 at its free end. The eye bolt 176 (FIG. 18) has a threaded shaft 177, a hex nut 178, and a head 179 with an eye 179a.

To connect the clamps 120, the shaft 177 of the eye bolt 176 is inserted into the mounting hole 133 in the platform 132 of one clamp 120, and the nut 178 is rotated onto the shaft 177. The head 179 is positioned between the gussets 134 of the other clamp 120, and the body 171 of the clamp pin 170 is inserted through both mounting holes 135 in the gussets 134 and through the eye 179a. The hooks 172 and the collar 173 on the clamp pin 170 maintain the clamp pin 170 in place.

When the clamps 120 are to be attached to a mounting pole 14, the technician may begin by inserting both clamp pins 170 as described above. The clips 175 can be used to clip the clamp pins 170 to the clamps 120 to prevent them from getting lost. The assembly 110 can be brought to the mounting pole 14, one of the clamp pins 170 can be removed from the eye bolt 176 (as in FIG. 19), and the clamps 120 may be opened to receive the mounting pole 14. The clamps 120 can then be clamped onto the mounting pole 14 and the clamp pin 170 can be replaced. The clamps 120 can be tightened by tightening one or both of the hex nuts 178. As shown in FIG. 18, one or more washers 179b may be included between the hex nut 178 and the platform 132.

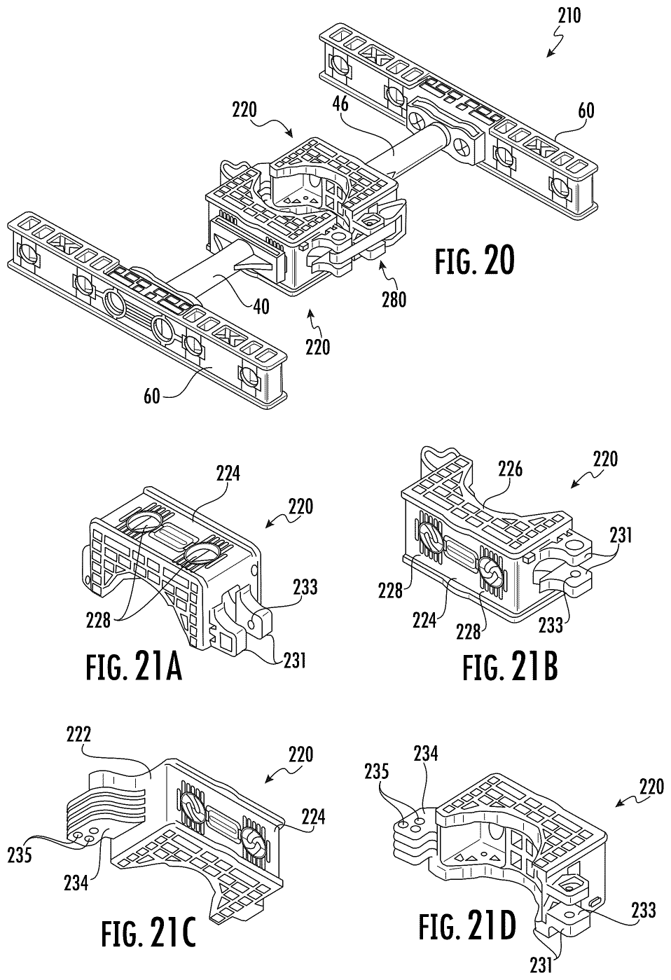

Referring now to FIGS. 20-23, another assembly, designated broadly at 210, is shown therein. The assembly 210 includes adapter extensions 40 and hanger panels 60 like those of the assemblies 10, 110, but utilizes clamps 220 that are configured to be secured together differently than the clamps 20, 120. As shown in FIGS. 21A-21D, each clamp 220 has a body 222, an outer surface 224 with mounting holes 228, and clamp surfaces 226 like the clamp 20. However, on one side of the body 222 the clamp 220 has two flanges 231, each with a mounting hole 233, and on the opposite side of the body 222 the clamp 220 has four wings 234, each with three mounting holes 235 arranged in a triangular pattern.

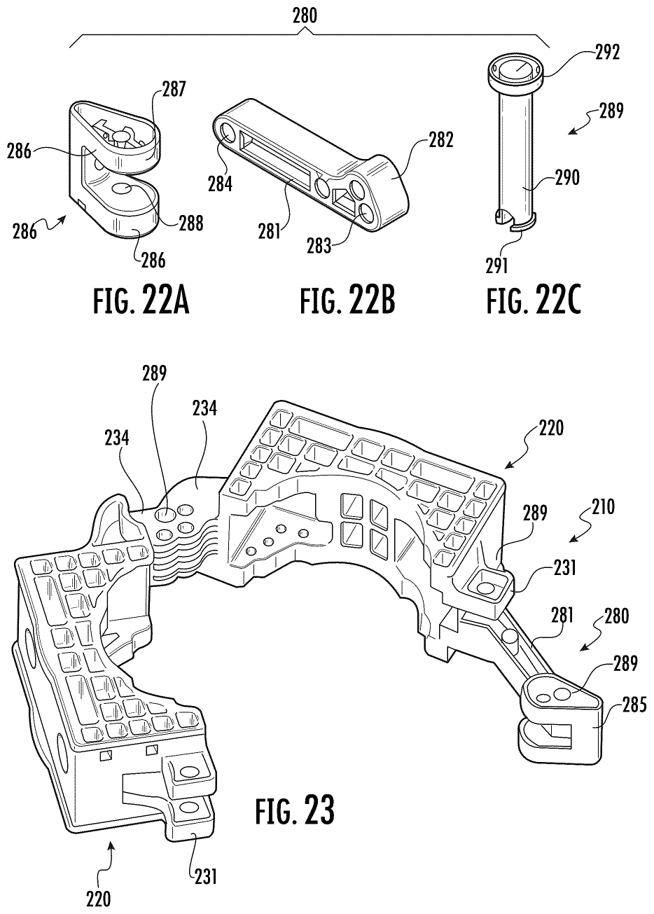

FIGS. 22A through 22C illustrate the components of a separate latch 280 used to attach the clamps 220 together. A latch link 281 has a triangular head 282 at one end with a hole 283, and also has a hole 284 at the opposite end. A latch lever 285 is generally U-shaped, with the arms 286 of the “U” being triangular with a rounded end 287. Holes 288 are present in the arms 286. A latch pin 289 has a shaft 290, hooks 291 at one end of the shaft 290, and a collar 292 at the opposite end.

To secure the clamps 220 together, the wings 234 of the clamps 220 are interleaved, and a latch pin 289 is inserted through one of the “columns” of mounting holes 235 in each clamp 220 (wherein the pattern of holes 235 provides some flexibility to accommodate mounting poles of different diameters). The latch link 281 is fastened to the flanges 231 of one of the clamps 220 via another latch pin 289 inserted through the holes 233 in the flanges and the hole 283 in the head of the latch link 281. The latch lever 285 is attached to the opposite end of the latch link 281 with a third latch pin 289, which is inserted through the holes 288 in the latch lever arms 286 and the hole 284 in the latch link 281. When the assembly 210 is mounted to a mounting pole 14, the latch link 281 is pivoted so that the latch lever 285 engages the flanges 231 on the other clamp 220, and the latch lever 285 is then pivoted so that its rounded ends 287 engage rounded surfaces of the flanges 231 to lock the latch 280 in place.

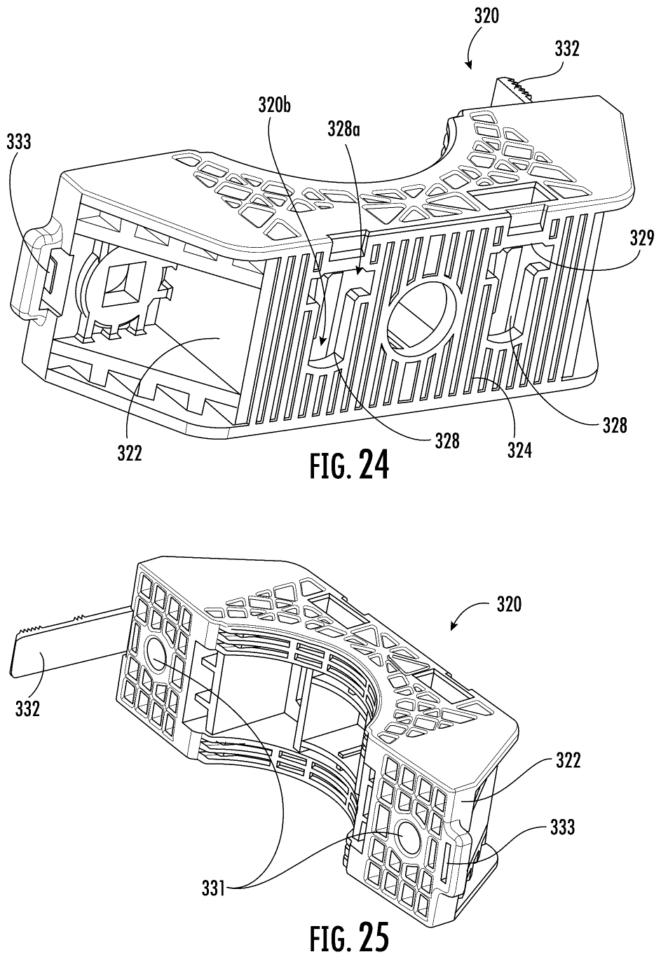

Referring now to FIGS. 24-33, another assembly, designated broadly at 310, is illustrated therein. Like the prior discussed assemblies, the assembly 310 includes two clamps 320, an adapter extension 340, and hanger panels 360, albeit of somewhat different configurations. Also, the assembly 310 may include a mounting adapter 380 to facilitate mounting of the adapter extension 340 and/or the hanger panel 360. All of these components are discussed in greater detail below.

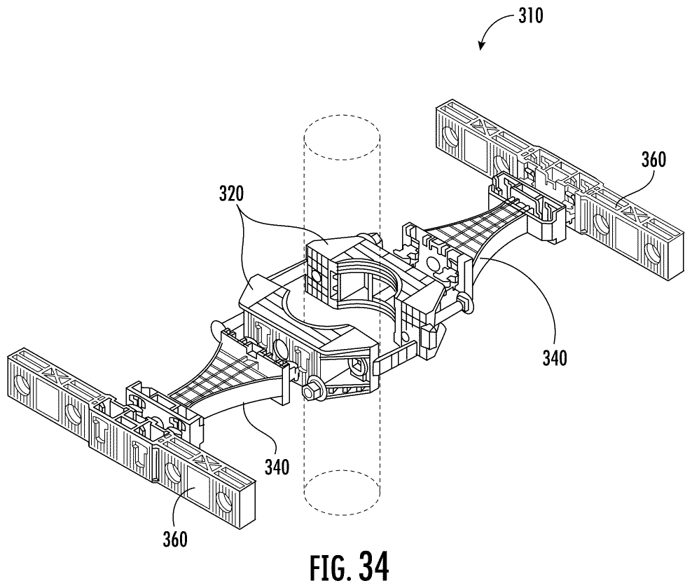

Referring to FIGS. 24 and 25, the clamp 320 has a body 322, an outer surface 324 with mounting openings 328, and clamp surfaces 326 like the clamp 20. However, the mounting openings 328 arc “T-shaped” openings, with an upper horizontal section 328a and lower vertical section 328b (see also FIG. 33A). Also, a shoulder 329 is present above each mounting opening 328, and an internal lower rim 333 is present in the vertical section 328b. Holes 331 extend through the body 322 on each side to receive a carriage bolt or the like (see FIG. 34). At one end, the clamp 320 includes a strap 332 that extends away from the outer surface 326, and at the opposite end the clamp 320 includes a loop 333 that is configured to receive the strap 332 from a second mating clamp 320.

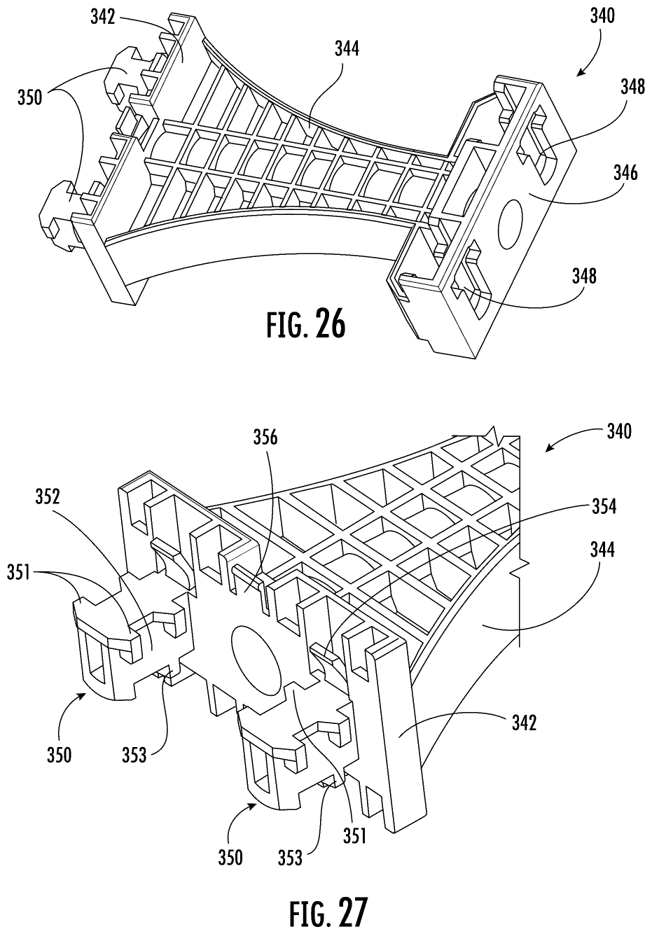

Referring now to FIGS. 26 and 27, the adapter extension 340 has a base 342 and a head 346 that is generally parallel with the base 342 like the adapter 40, but these components are connected by a tapering body 344 that extends from the base 342 to the head 346. The head 346 includes two T-shaped openings 348 that are similar in shape to the T-shaped openings 328 of the clamp 320. At the opposite end of the adapter extension 340, two latches 350 extend away from the base 342. The body 352 of each latch 350 is generally rectangular in cross-section. Wings 351 extend laterally from the body 352. The wings 351 and body 352 are sized and configured to fit into the T-shaped openings 328 on the base 320, with the body 352 being shorter in height than the T-shaped opening 328. A lower lip 353 depends from the lower surface of the body 352. In addition, a curved finger 354 extends upwardly from the body 352 and slightly rearwardly away from the tapering body 344, and a support member 356 extends upwardly between the T-shaped latches 350.

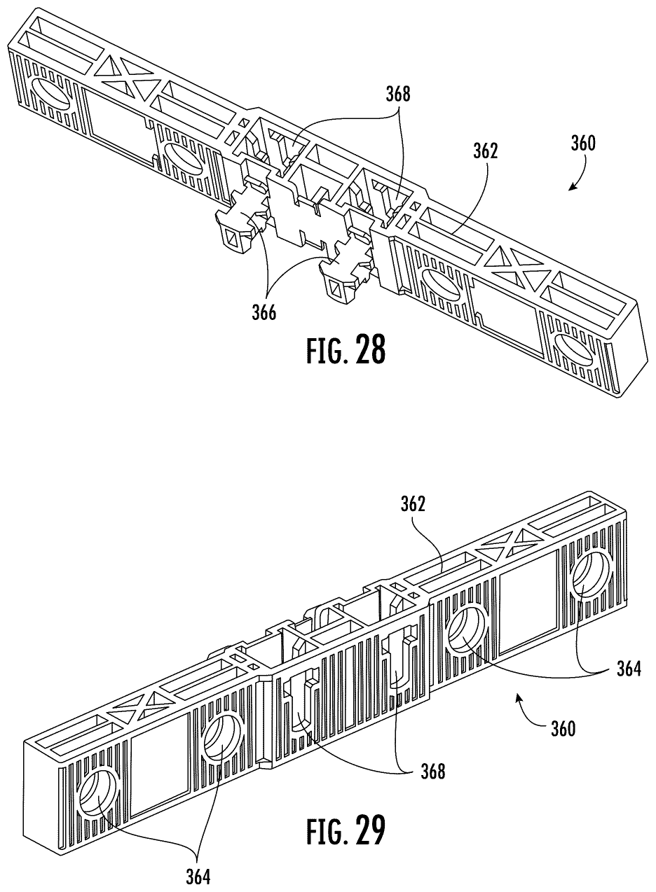

Referring now to FIGS. 28 and 29, the hanger panel 360 is similar to the hanger panel 60, with a generally rectangular skeletal base 362 and four mounting holes 364 (typically having a nominal diameter of ¾ inch) are spaced across both the front and rear surfaces of the base 362. Two T-shaped latches 366 extend from the rear surface of the base 362; the latches 366 are similar to the latches 348 described above and are sized and positioned to fit within the T-shaped openings 348 of the adapter extension 340 or the or the T-shaped openings 328 in the clamp 320. On its front surface, the base 362 has two T-shaped openings 368 that are sized and configured to receive T-shaped latches from the mounting adapter 380 (described below).

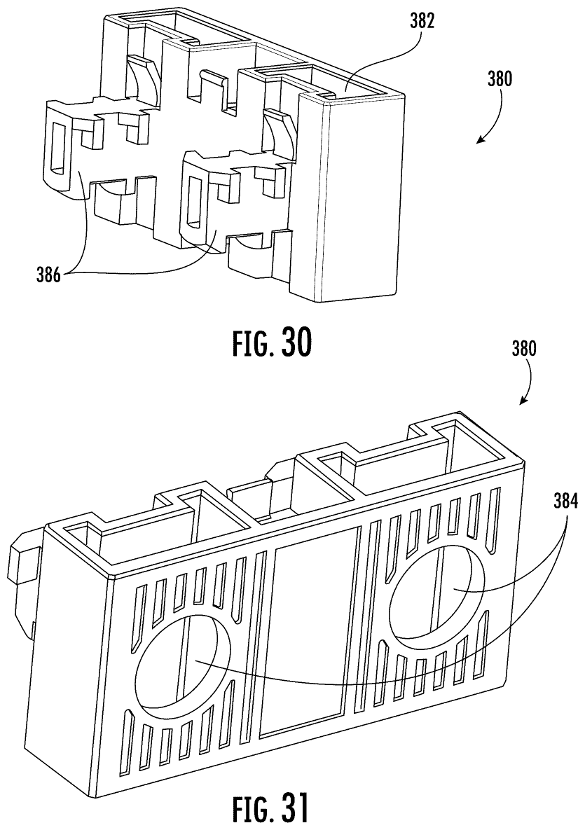

Referring now to FIGS. 30 and 31, the mounting adapter 380 is generally rectangular with a skeletal base 382 and mounting holes 384 (typically nominally ¾ inch in diameter) on the front surface of the base 382. Two T-shaped latches 386 extend rearwardly from the base 382.

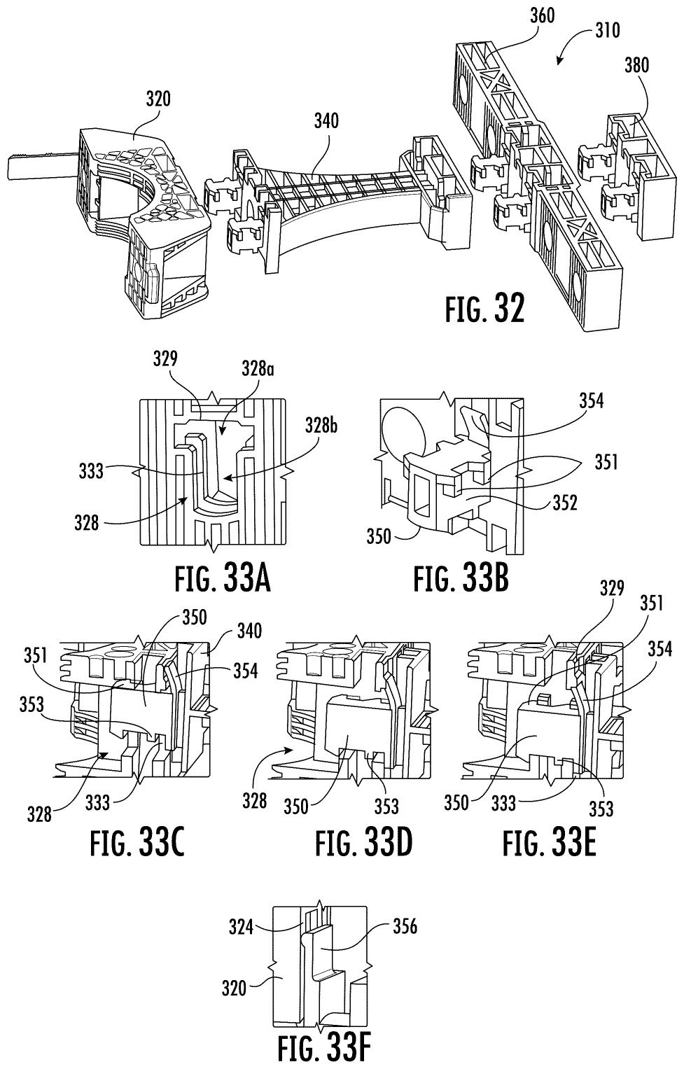

FIG. 32 illustrates one particular configuration for the assembly 310. In this configuration, the adapter extension 340 is mounted to the clamp 320 via the T-shaped latches 350, which are inserted into the T-shaped openings 328 in the clamp 320 (details of the mounting of any of various T-shaped latches in any of the T-shaped openings are set forth below). The hanger panel 360 is mounted to the head 346 of the adapter extension 340 via the insertion of the T-shaped latches 366 into the T-shaped openings 348. The mounting adapter 380 is mounted to the hanger panel 360 via insertion of the T-shaped latches 386 into the T-shaped openings 368. In this configuration, the hanger panel 360 and the mounting adapter 380 provide mounting locations (in the form of the mounting holes 364 and 384) for cable hangers) similar to that shown in FIG. 12 above, but with additional mounting locations provided by the mounting holes 384 of the mounting adapter 380. In some embodiments, the assembly 310 may omit the mounting adapter 380, in which case the assembly 310 provides the same number of mounting locations as that shown in FIG. 12.

Those skilled in this art will appreciate that the arrangements shown in FIGS. 10 and 11 can also be achieved with the assembly 310. More specially, the arrangement shown in FIG. 10 can be created by mounting the mounting adapter 380 directly onto the clamp 320 (with the T-shaped latches 386 being inserted into the T-shaped openings 328). The arrangement shown in FIG. 11 can be achieved by mounting the hanger panel 360 directly onto the clamp 320, (with the T-shaped latches 366 being inserted into the T-shaped openings 328). This arrangement may be augmented by the mounting of the mounting adapter 380 onto the hanger panel 360.

Referring now to FIGS. 33A-33E, the mounting of any of the T-shaped latches into any of the T-shaped openings is illustrated therein (using the T-shaped latch 350 and the T-shaped opening 328 as examples). As shown in FIG. 33C, the T-shaped latch 350 is inserted into the T-shaped opening 328, with the wings 351 slipping into the horizontal section 328 of the T-shaped opening 328 and the body 352 slipping into the vertical section 328b. Once the T-shaped latch 350 is fully inserted, it is lowered (see FIGS. 33D and 33E) until it “bottoms out” in the vertical section 328b of the T-shaped opening 328. In the position the wings 351 and the lower lip 353 of the T-shaped latch 350 have advanced rearwardly and downwardly sufficiently to capture the rim 333 and the rearward edge of the T-shaped opening 328 (see FIG. 33E).

In addition, the finger 354 descends with the T-shaped latch 350 (flexing as it descends) until it reaches the shoulder 329, at which point it recovers partially from its deflection to fit within the shoulder 329 (see FIG. 33E). In this position, the finger 354 can provide rearward pressure to the clamp 320 to help “lock” the adapter extension 340 in place, and also provides a stop against upward movement of the adapter extension 340 relative to the clamp 320. The support member 356 also applies further rearwardly-directed pressure against the outer surface of the clamp 320 (see FIG. 33F).

As shown in FIG. 34, two clamps 320 can be attached to a mounting pole (shown in broken line in FIG. 34) via carriage bolts 390 or other fasteners that are inserted into holes 331. Straps 332 are inserted into loops 333 on each side of the clamps 320 to assist with alignment during mounting and/or to provide additional stability.

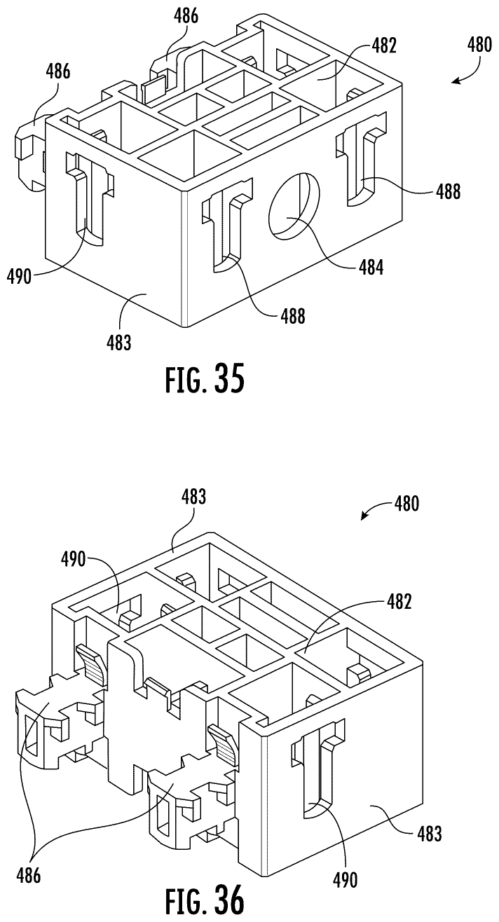

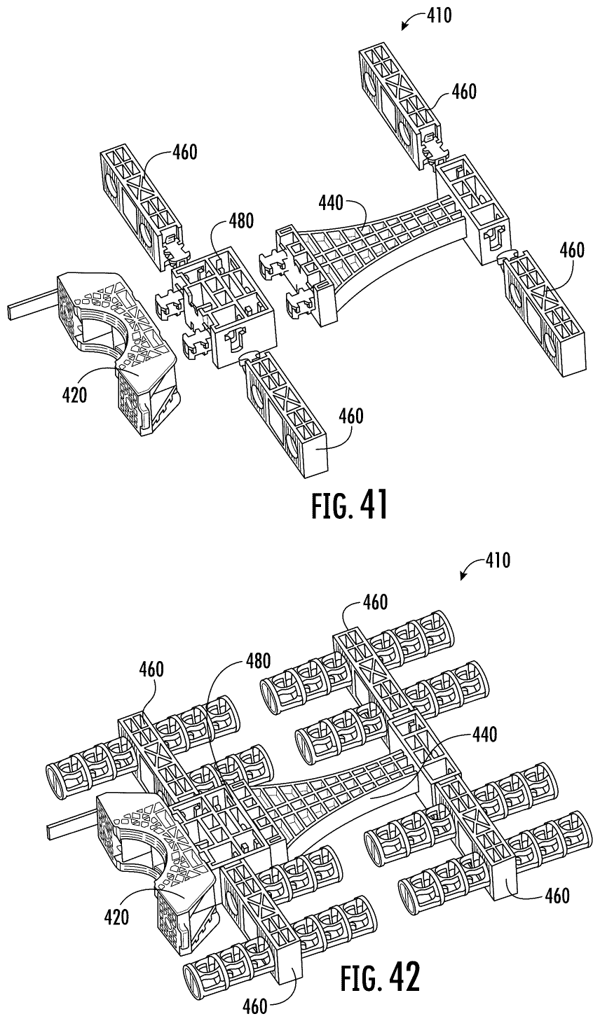

Referring now to FIGS. 35-42, another assembly, designated broadly at 410, is illustrated therein. Like the prior discussed assembly, the assembly 410 includes two clamps 420 (only one of which is shown in FIGS. 41 and 42), an adapter extension 440, hanger panels 460, and a mounting adapter 480, albeit of somewhat different configurations (with the exception of the clamps 420, which are the same as the clamps 320). The other components are discussed in greater detail below.

Referring to FIGS. 35 and 36, the mounting adapter 480 is generally rectangular with a skeletal base 482 and one mounting hole 484 (typically nominally ¾ inch in diameter) on the front surface of the base 482. Two T-shaped latches 486 similar to those described above extend rearwardly from the base 482. The mounting adapter 480 includes T-shaped openings 488 on its front surface on either side of the mounting hole 484. The mounting adapter 480 further includes a T-shaped opening 490 on each side wall 483.

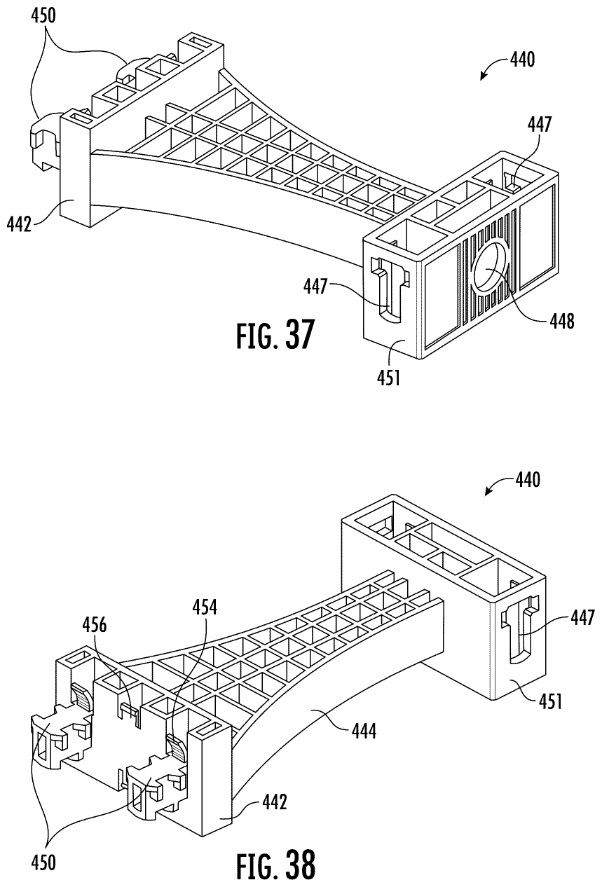

Referring now to FIGS. 37 and 38, the adapter extension 440 has a base 442 and a head 446 that is generally parallel with the base 442, and a tapering body 444 that extends from the base 442 to the head 446. The head 446 includes a mounting hole 448 on its front surface and two T-shaped openings 447 (one on each side wall 451). At the opposite end of the adapter extension 440, two T-shaped latches 450 similar to those described above extend away from the base 442. The adapter extension 440 also includes a curved finger 454 and a support member 456 similar to those described above.

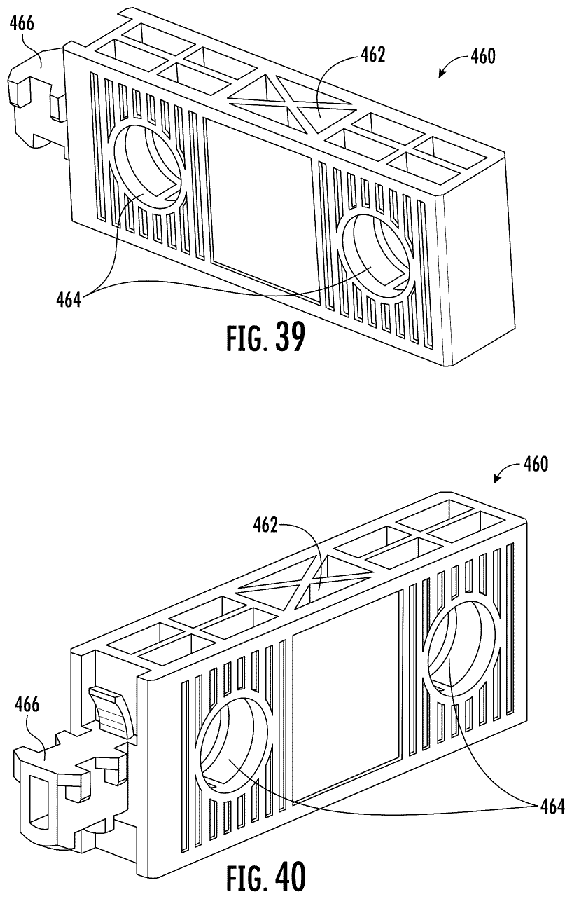

Referring now to FIGS. 39 and 40, the hanger panel 460 has a generally rectangular skeletal base 462 and two mounting holes 464 (typically having a nominal diameter of ¾ inch) on each of the front and rear surfaces of the base 462. A T-shaped latch 466 similar to those described above extends from the side surface 463 of the base 462.

One arrangement of the assembly 410 is shown in FIGS. 41 and 42. In this arrangement, the mounting adapter 480 is mounted onto the clamp 420 via the T-shaped latches 486 being inserted into the T-shaped openings in the clamp 420. The adapter extension 440 is mounted to the mounting adapter 480 via the T-shaped latches 450 being inserted into the T-shaped openings 488. One or more hanger panels 460 can then be mounted onto the side surfaces of either (or both) of the mounting adapter 480 and the head 446 of the adapter extension 440; the T-shaped latches 466 are inserted into the T-shaped openings 447, 488; as shown in FIGS. 41 and 42, the hanger panels 460 can be mounted on both sides of the adapter extension 440 and/or the mounting adapter 480. Cable hangers can then be mounted on the mounting holes 464 on the front and rear surface of the hanger panels 460 as well as in the mounting hole 484 in the adapter extension 440.

Those of skill in this art will appreciate that the assembly 410 may omit the adapter extension 440, in which case the hanger panels 460 can be mounted on the mounting adapter 480 only. In another embodiment, the mounting adapter 480 may be omitted, such that hanger panels 460 are mounted only on the adapter extension 440.

In a further embodiment, it can be conceived that the clamp 420 and the mounting adapter 480 may be formed as an integral unit.

Notably, all of the clamps 20, 120, 220, 320, 420 are configured so that they can be used with an identical mating clamp 20, 120, 220, 320. This can reduce tooling costs and labor in manufacturing as well as simplifying assembly.

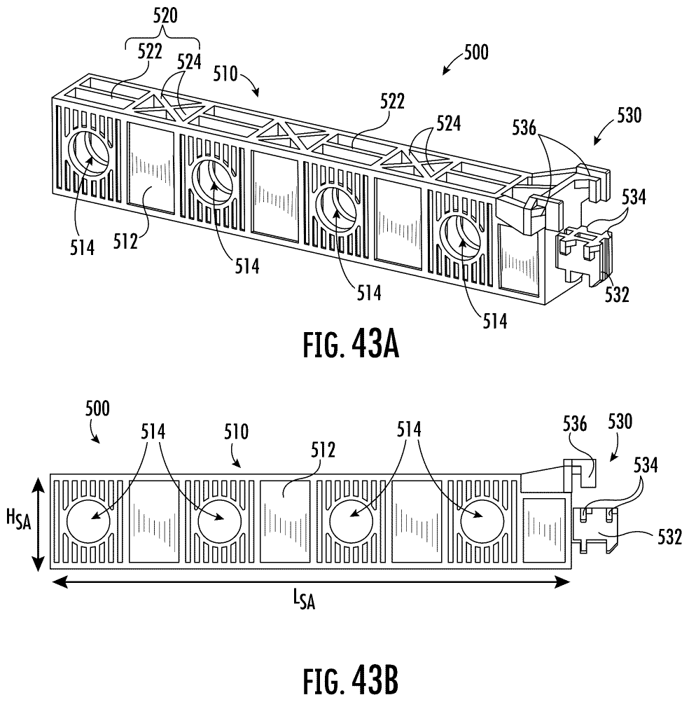

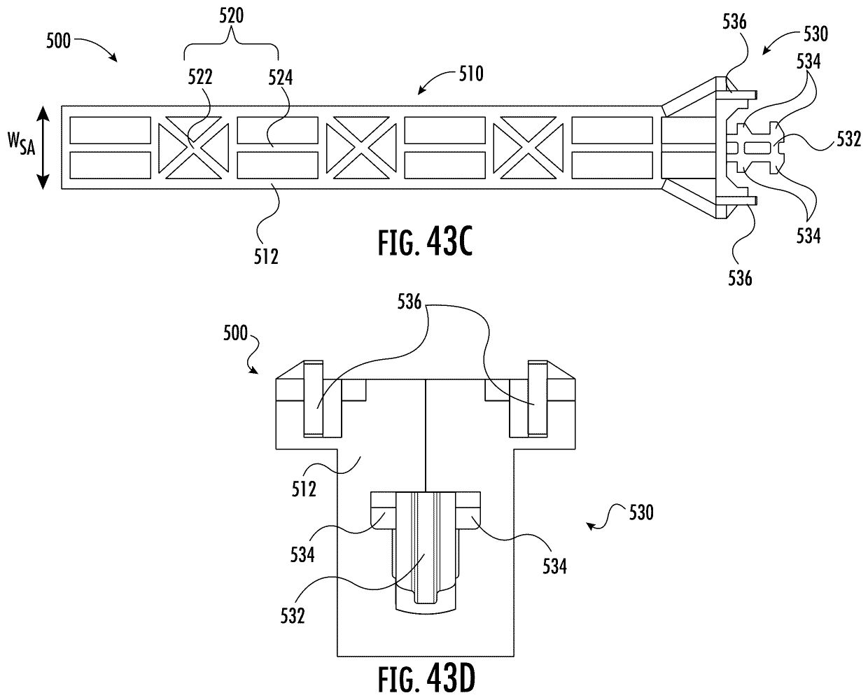

Referring to FIGS. 43A-43D, an alternative hanger panel (or straight arm adapter) 500 according to embodiments of the present invention is illustrated. As shown in FIGS. 43A-43D, in some embodiments, the hanger panel 500 has a generally rectangular skeletal base 510 having a length LSA, a width WSA and a height HsA. In some embodiments, the base 510 has a length LSA of about 230 mm, a width WsA of about 29 mm, and a height HsA of about 42 mm. One or more securing mechanisms 530 are coupled to or integral with an end of the base 510 (extending axially outwardly thereform). In some embodiments, the base 510 may comprise a plurality of support beams 520. In some embodiments, the plurality of support beams 520 may include axial beams 522 and/or cross beams 524. A plurality of mounting holes 514 (typically having a nominal diameter of ¾ inch) are spaced apart on opposing side surfaces 512 along the length L_{SA} of the base 510. In some embodiments, the mounting holes 514 may be spaced apart from each other a distance of about 58 mm. In some embodiments, the hanger panel 500 is formed from a polymeric material.

In some embodiments, one of the securing mechanisms 530 of the hanger panel 500 includes a latch 532 extending from the end of the base 510. The latch 532 may include a plurality of wings 534 extending radially outwardly therefrom and a lower lip 536 extending downwardly therefrom. In some embodiments, the latch 532 is sized and configured to fit within a corresponding recess 630 of an alternative adapter extension 600, as described in further detail below. In some embodiments, one of the securing mechanisms 530 of the hanger panel 500 may include a pair of hooks 536 extending from the end of the base 510. In some embodiments, the pair of hooks 536 reside above the latch 532. As described in further detail below, in some embodiments, the hooks 536 are configured to engage a top edge of the adapter extension 600.

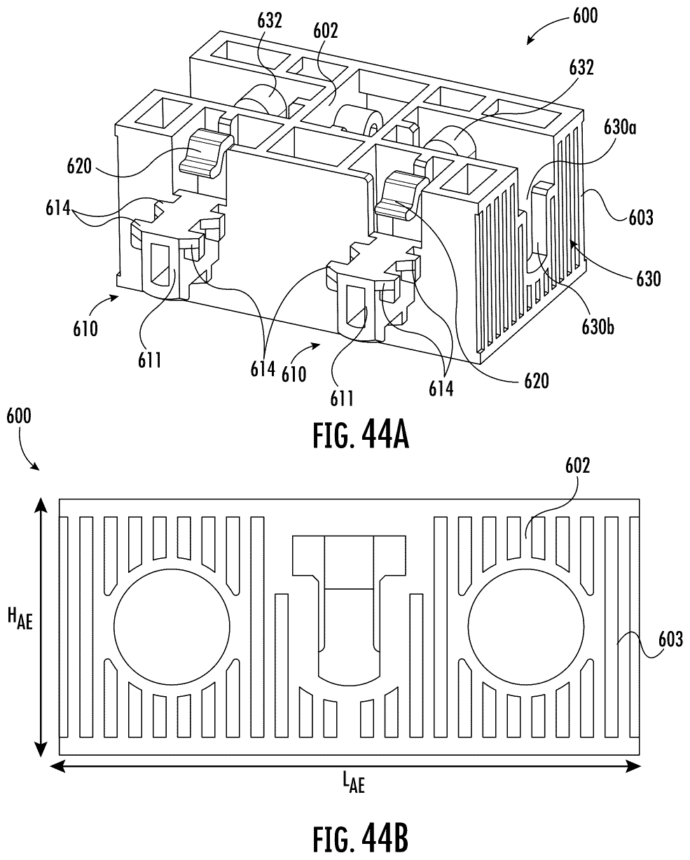

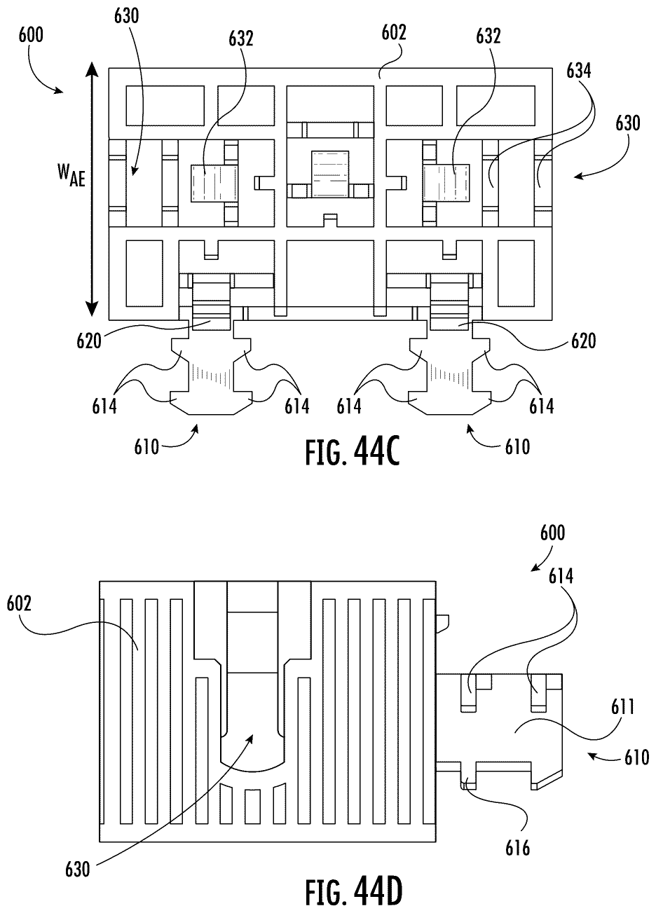

Referring to FIGS. 44A-44D, the adapter extension 600 according to embodiments of the present invention is illustrated. As shown in FIGS. 44A-44C, in some embodiments, the adapter extension 600 has a generally rectangular skeletal base 602 having four side walls 603. In some embodiments, the adapter extension 600 has a length L_{AE} of about 95 mm, a width W_{AE} of about 54 mm, and a height H_{AE} of about 42 mm. The base 602 comprises a recess 630 in one or more of the side walls 603. In some embodiments, the adapter extension 600 is formed from a polymeric material.

As described in further detail below, in some embodiments, each recess 630 of the adapter extension 600 is configured to receive the latch 532 of the hanger panel 500. For example, in some embodiments, the latch 532 is received by an open end 630a of the recess 630 and configured to slide down a vertical section 630b of the recess 630 until the latch 532 “bottoms out” in the vertical section 630b of the recess 630. As the latch 532 is received in the recess 630, the wings 534 of the latch 532 engage support members 634 of the adapter extension 600 residing within the recess 630. In some embodiments, when in position, the latch 532 has advanced rearwardly and downwardly sufficiently until a securing mechanism 632 of the adapter extension 600 is deflected and engages the latch 532, thereby securing the hanger panel 500 to the adapter extension 600. In some embodiments, the pair of hooks 536 engage a top edge of the adapter extension 600, thereby further securing the hanger panel 500 to the adapter extension 600.

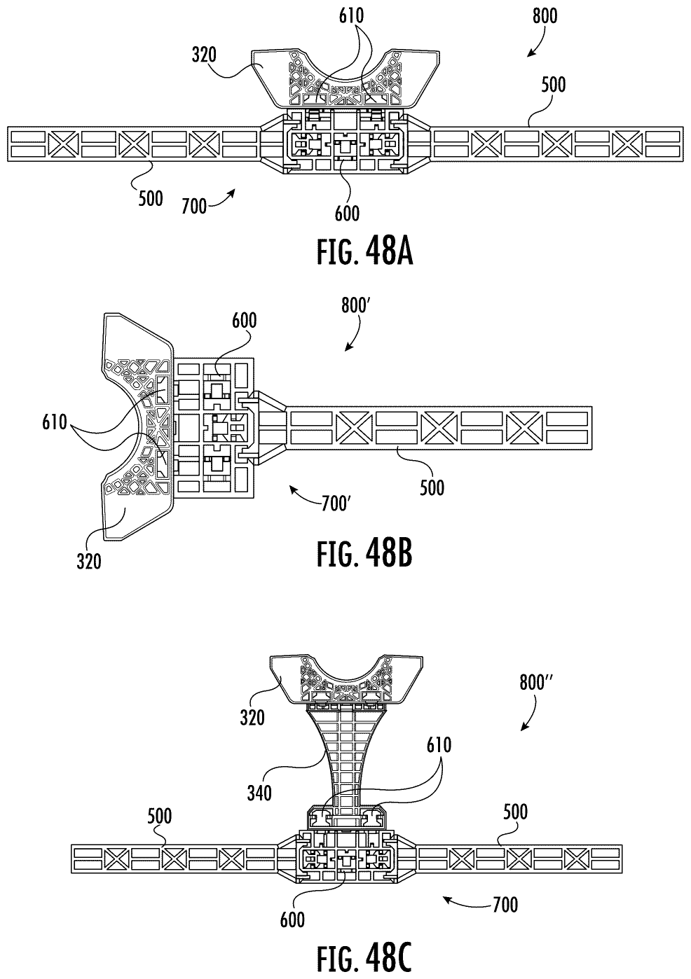

In some embodiments, the adapter extension 600 further comprises a pair of latches 610 extending outwardly from one of the side walls 603. In some embodiments, similar to the latch 532 of the hanger panel 500, each latch 610 of the adapter extension 600 may comprise wings 614 and a lower lip 616 extending outwardly therefrom. In some embodiments, the latches 610 of the adapter extension 600 are configured to be received by the T-shaped opening 328 of the clamp 320 or T-shaped opening 348 of the adapter extension 340 described herein (see, e.g., FIGS. 48A-48C).

For example, in some embodiments, the wings 614 of the latch 610 are configured to slide into the horizontal section 328a of the T-shaped opening 328 of the clamp 320 and the body 611 of the latch 610 is configured to slide into the vertical section 328b of the T-shaped opening 328 of the clamp 320. Once the respective latches 610 are fully inserted, they are lowered until each “bottoms out” in the vertical section 328b of the T-shaped opening 328. In some embodiments, when in position, the wings 614 and the lower lip 616 of each latch 610 have advanced rearwardly and downwardly sufficiently to capture the rim 333 and the rearward edge of the T-shaped opening 328 (see, e.g., FIGS. 48A-48B). In some embodiments, the latches 610 of the adapter extension 600 are configured to be received in the T-shaped openings 348 of the adapter extension 340 in a similar manner (see, e.g., FIG. 48C).

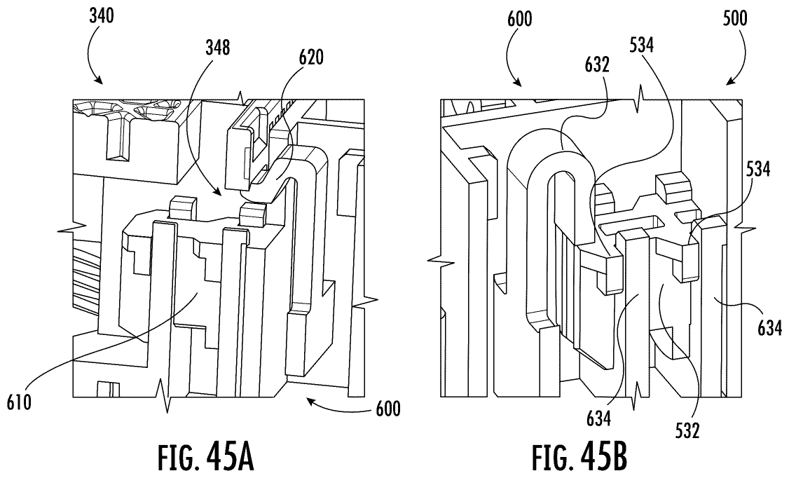

In some embodiments, the adapter extension 600 may further include one or more securing mechanisms 620, 632. In some embodiments, the one or more securing mechanisms 620, 632 may be snap-fit securing mechanisms. In some embodiments, a first securing mechanism 620 may reside above a respective latch 610 and is configured to secure the latch 610 within the T-shaped opening 328 of the clamp 320 or the T-shaped opening 348 of the adapter extension 340 (when inserted therein) (see, e.g., FIG. 45A). In some embodiments, a second securing mechanism 632 may reside within a respective recess 630 and is configured to secure the latch 532 of the hanger panel 500 (when inserted therein) (see, e.g., FIG. 45B).

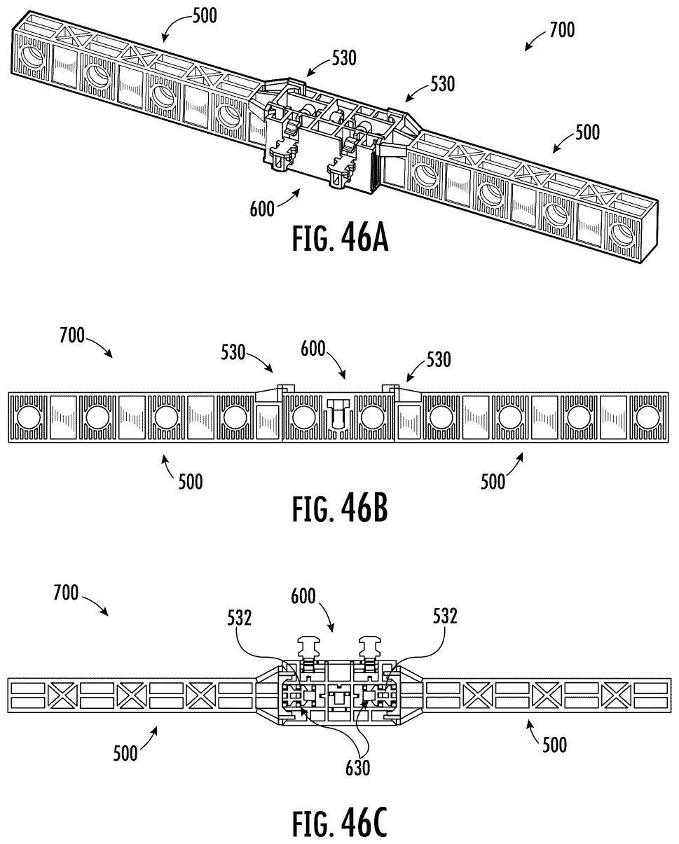

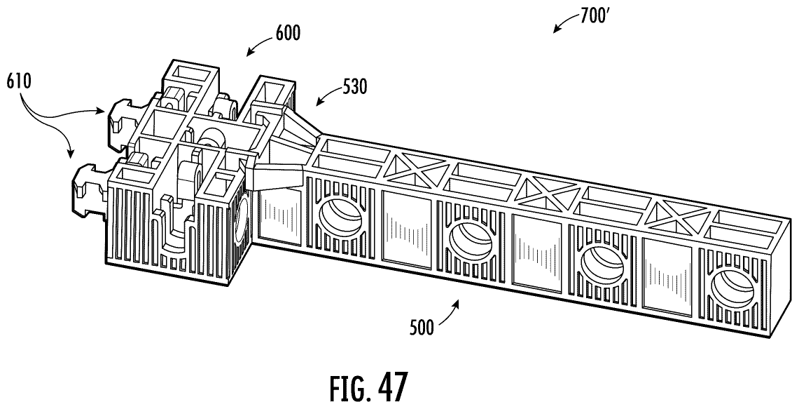

FIGS. 46A-46C and FIG. 47 illustrate assemblies 700, 700′ according to embodiments of the present invention which have different configurations that the hanger panel 500 and adapter extension 600 may be utilized. As shown in FIGS. 46A-46C, the assembly 700 includes two hanger panels 500 secured to opposing side walls 603 of the adapter extension 600 (via securing mechanisms 530). For example, as shown in FIG. 46C, the latch 532 of each hanger panel 500 is received within respective recesses 630 of the adapter extension 600. As shown in FIG. 47, the assembly 700′ includes one hanger panel 500 secured to a side wall 603 opposing the latches 610 (via securing mechanism 530).

FIGS. 48A-48C illustrate assemblies 800, 800′, 800″ which show different configurations that may be formed utilizing the components of the present invention described herein. As shown in FIG. 48A, in some embodiments, the assembly 700 (i.e., two hanger panels 500 and adapter extension 600) may be secured to clamp 320 (via latches 610 of the adapter extension 600). As shown in FIG. 48B, in some embodiments, the assembly 700′ (i.e., one hanger panel 500 and adapter extension 600) may be secured to the clamp 320 (via latches 610 of the adapter extension 600). As shown in FIG. 48C, in some embodiments, the assembly 700 may be secured to adapter extension 340 via latches 610 of the adapter extension 600 (the adapter extension 340 being further secured to clamp 320).

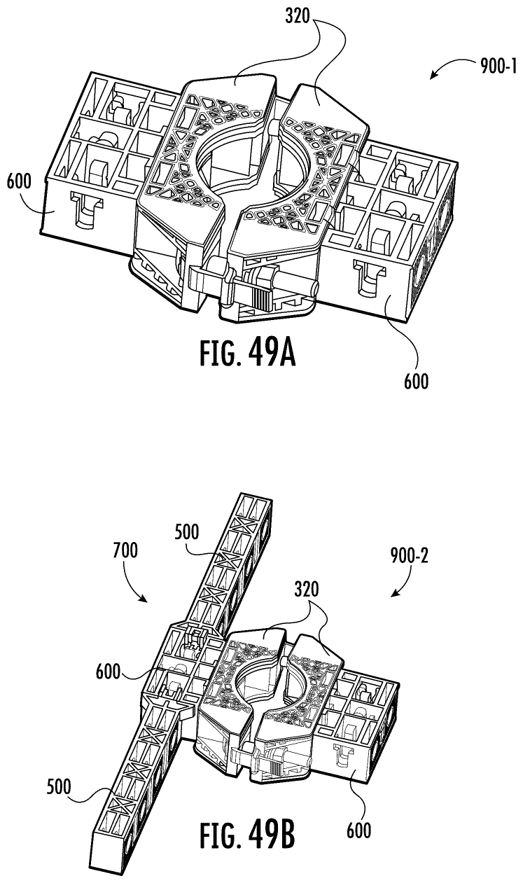

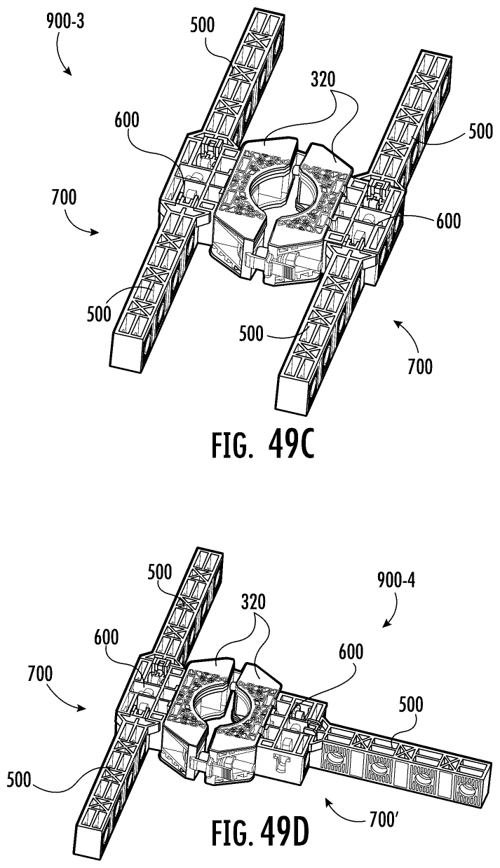

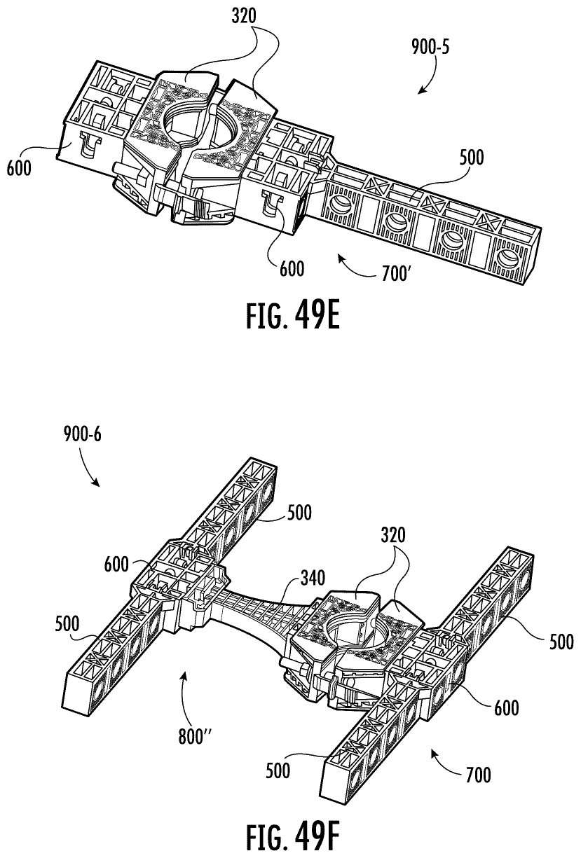

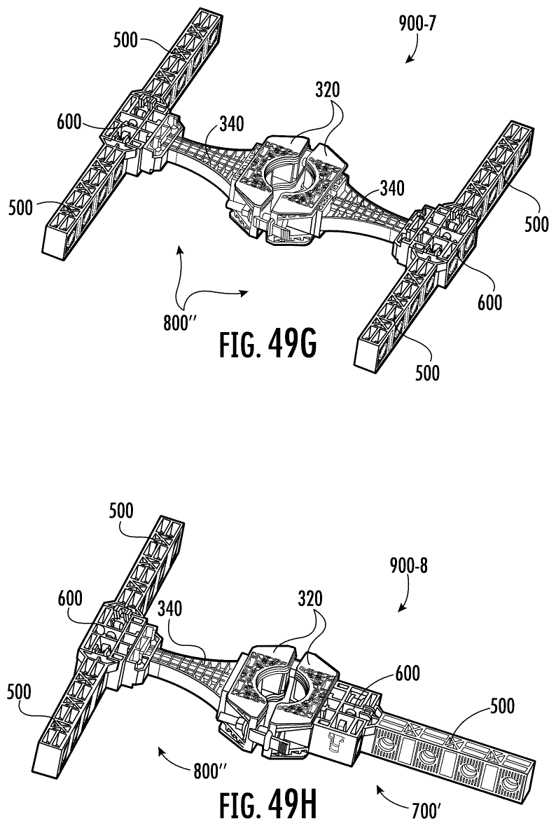

FIGS. 49A-49H illustrate assemblies 900-1 to 900-8 which show further exemplary configurations that may be formed utilizing the hanger panel 500, adapter extension 600, adapter extension 340 and clamps 320 described herein. It will be understood by those of skill in this art that the assemblies 110, 210, 310, 410, 700, 700′, 800, 800′, 800″, and 900-1 to 900-8 can be used to create any of the configurations of adapter extensions and hanger panels shown in FIGS. 6-12, FIGS. 48A-48C, and FIGS. 49A-49H. It will also be understood by those of skill in the art that the configurations are not limited to those shown in the figures.

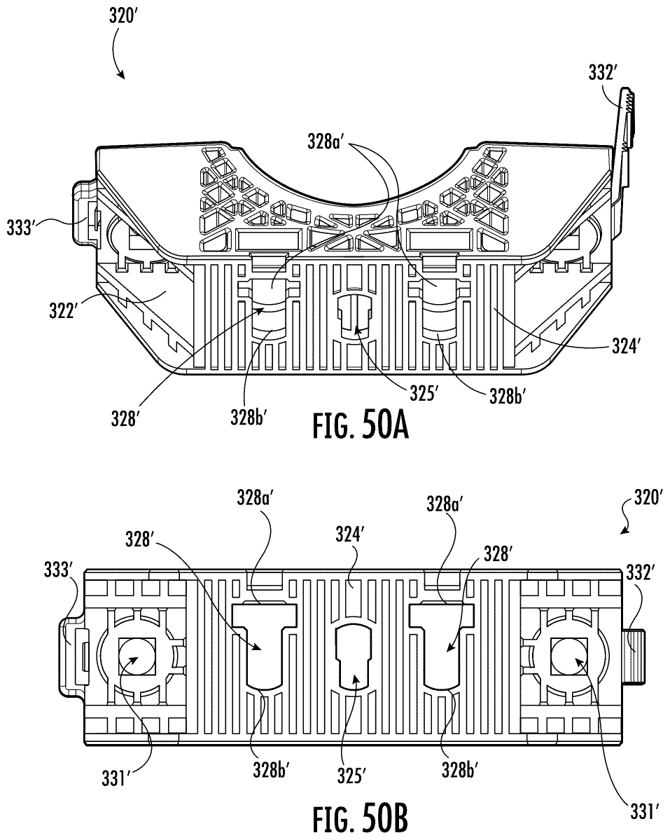

Referring to FIGS. 50A-50B, an alternative clamp 320′ according to embodiments of the present invention is illustrated. Properties and/or features of the clamp 320′ may be as described above in reference to the clamp 320 shown in FIG. 24 and FIG. 25 and duplicate discussion thereof may be omitted herein for the purposes of discussing FIGS. 50A-50B.

As shown in FIGS. 50A-50B, the clamp 320′ has a body 322′, an outer surface 324′ with mounting openings 328′, and clamp surfaces 326′ like the clamp 320. The mounting openings 328′ are “T-shaped” openings, with an upper horizontal section 328a′ and lower vertical section 328b′. Also, a shoulder 329′ is present above each mounting opening 328′ (sec, e.g., FIG. 54B). Holes 331′ extend through the body 322′ on each side to receive a carriage bolt or the like. At one end, the clamp 320′ includes a strap 332′ that extends away from the outer surface 326′, and at the opposite end the clamp 320′ includes a loop 333′ that is configured to receive the strap 332′ from a second mating clamp 320′.

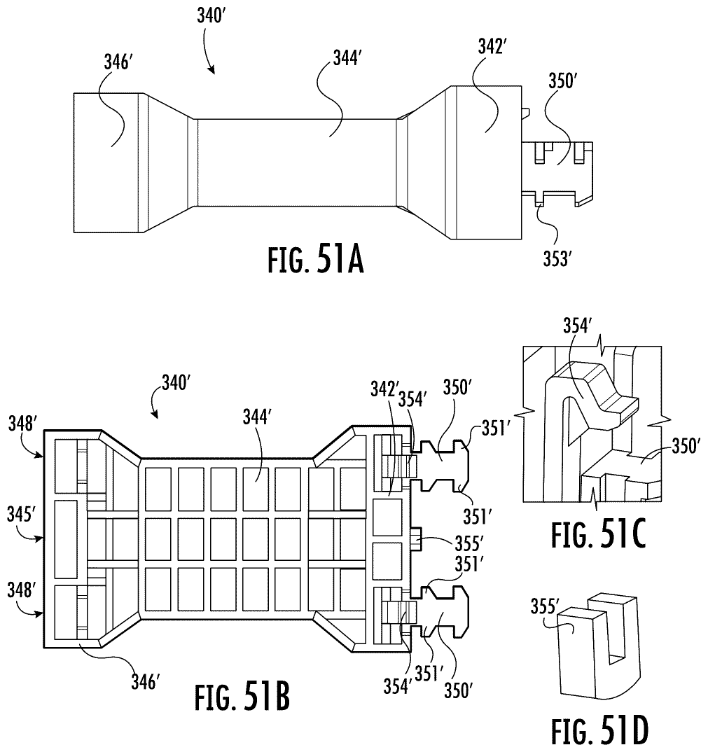

The clamp 320′ differs from clamp 320 described herein in that the outer surface 324′ of the clamp 320′ further includes an aperture 325′ residing between the mounting openings 328′. The aperture 325′ is configured to receive and/or engage with a corresponding positioning feature 355′, 365′ of an adapter extension 340′ or hanger panel 360′ (sec, e.g., FIGS. 51B, FIG. 51D, FIG. 52, FIGS. 53A-53B, and FIGS. 55A-55B) when the adapter extension 340′ or hanger panel 360′ is secured to the clamp 320′. As described in further detail below, the positioning features 355′, 365′ may help to prevent rotation and shaking between the components after installation.

Referring to FIGS. 51A-51B, an alternative adapter extension 340′ according to embodiments of the present invention is illustrated. Properties and/or features of the adapter extension 340′ may be as described above in reference to the adapter extension 340 shown in FIG. 26 and FIG. 27 and duplicate discussion thereof may be omitted herein for the purposes of discussing FIGS. 51A-51B.

As shown in FIGS. 51A-51B, similar to the adapter extension 340 described herein, the adapter extension 340′ has a base 342′ and a head 346′ that is generally parallel with the base 342′. The head 346′ includes two T-shaped openings 348′ that are similar in shape to the T-shaped openings 328′ of the clamp 320′. At the opposite end of the adapter extension 340′, two latches 350′ extend away from the base 342′. Each latch 350′ is generally rectangular in cross-section. Wings 351′ extend laterally from the latch 350′. The wings 351′ and latch 350′ are sized and configured to fit into the T-shaped openings 328′ on the clamp 320′, with the latch 350′ being shorter in height than the T-shaped opening 328′. A lower lip 353′ depends from the lower surface of the latch 350′.

The adapter extension 340′ differs from the adapter extension 340 in that the body 344′ of the adapter extension 340′ does not continuously taper as it extends from the base 342′ to the head 346′ (compare adapter extension 340′ with the adapter extension 340 shown in FIG. 26). The adapter extension 340′ may have increased strength compared to the adapter extension 340 described herein. As shown in FIG. 51C, in some embodiments, the curved finger 354 of the adapter extension 340 may be replaced with an alternative securing mechanism 354′ that is configured to engage with the shoulder 329′ of the clamp 320′ to help secure the components together (see also, e.g., FIG. 54B). As discussed above, as shown in FIG. 51B and FIG. 51D, the adapter extension 340′ further includes a positioning feature 355′ extending outwardly from the base 342′. The positioning feature 355′ is configured to be received by the aperture 325′ of the clamp 320′. The position feature 355′ helps to prevent rotation and shaking between the adapter extension 340′ and the clamp 320′ and secured together.

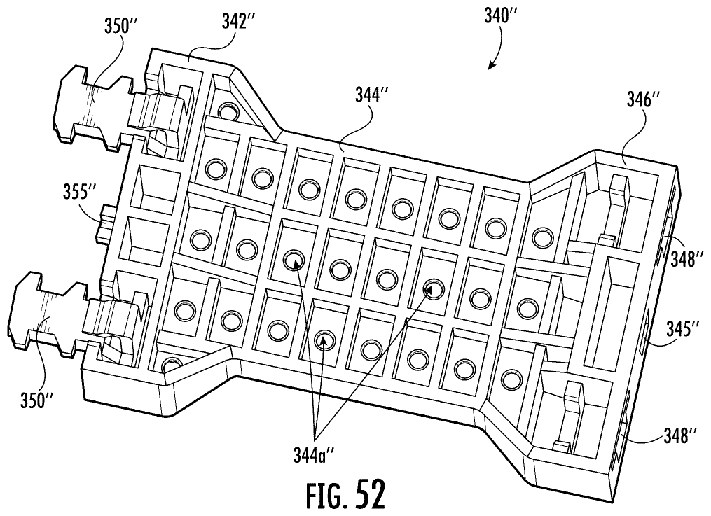

Referring to FIG. 52, an alternative adapter extension 340″ according to embodiment of the present invention is illustrated. Properties and/or features of the adapter extension 340″ may be as described above in reference to the adapter extension 340′ shown in FIGS. 51A-51B and duplicate discussion thereof may be omitted herein for the purposes of discussing FIG. 52. As shown in FIG. 52, the adapter extension 340″ differs from the adapter extension 340′ described herein in that the body 344″ of the adapter extension 340″ includes a plurality of draining holes 344a″. The draining holes 344a″ help to prevent water from collecting (and freezing) on the adapter extension 340″, thereby helping to avoid mold and/or additional load weight on the adapter extension 340″.

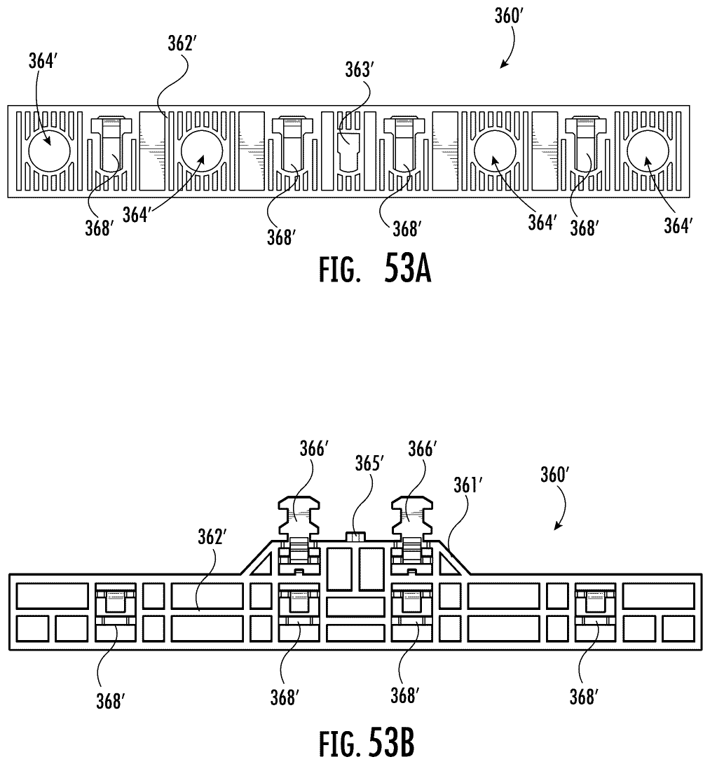

Referring to FIGS. 53A-53B, an alternative hanger panel 360′ according to embodiments of the present invention is illustrated. Properties and/or features of the hanger panel 360′ may be as described above in reference to the hanger panel 360 shown in FIG. 28 and FIG. 29 and duplicate discussion thereof may be omitted herein for the purposes of discussing FIGS. 53A-53B.

As shown in FIGS. 53A-53B, the hanger panel 360′ is similar to the hanger panel 360, with a generally rectangular skeletal base 362′ and four mounting holes 364′ (typically having a nominal diameter of ¾ inch) are spaced across both the front and rear surfaces of the base 362′. Two T-shaped latches 366′ extend from the rear surface of the base 362′; the latches 366′ are similar to the latches 350′ described above and are sized and positioned to fit within the T-shaped openings 348, 348′ of the adapter extensions 340, 340′ or the or the T-shaped openings 328, 328′ in the clamps 320, 320′. On its front surface, the base 362′ has two T-shaped openings 368′ that are sized and configured to receive T-shaped latches from the mounting adapter 380 or adapter extensions 340, 340′, 600 described herein.

The hanger panel 360′ differs from the hanger panel 360 described herein in that, in some embodiments, the rear surface of the base 362′ of the hanger panel 360′ includes additional structural support 361′ adjacent to where the latches 366′ extend outwardly. In addition, as described above, the hanger panel 360′ includes a positioning feature 365′ residing between the latches 366′. The positioning feature 355′ is configured to be received by the aperture 325′ of the clamp 320′ or aperture 345′ of the adapter extension 340′. Similar to the position feature 355′ of the adapter extension 240′, the position feature 355′ of the hanger panel 360′ helps to prevent rotation and shaking between the hanger panel 360′ and the clamp 320′ or adapter extension 340′ when secured together. In some embodiments, the hanger panel 360′ may also include similar securing mechanisms as the adapter extension (e.g., securing mechanism 354′ shown in FIG. 54B).

FIGS. 54A-54B compare the securing mechanism of the adapter extension 340 described herein (i.e., curved finger 354) (FIG. 54A) with the alternative securing mechanism 354′ of the adapter extension 340′ (FIG. 54B) and corresponding engagement of the respective securing mechanisms 354, 354′ with the shoulder 329, 329′ of clamp 320, 320′ when the respective adapter extensions 340, 340′ are engaged therewith. In some embodiments, the alternative securing mechanism 354′ may allow for easier disassembly of the engaged components (e.g., the components may be disassembled directly by hand rather than needing a tool such as a screwdriver).

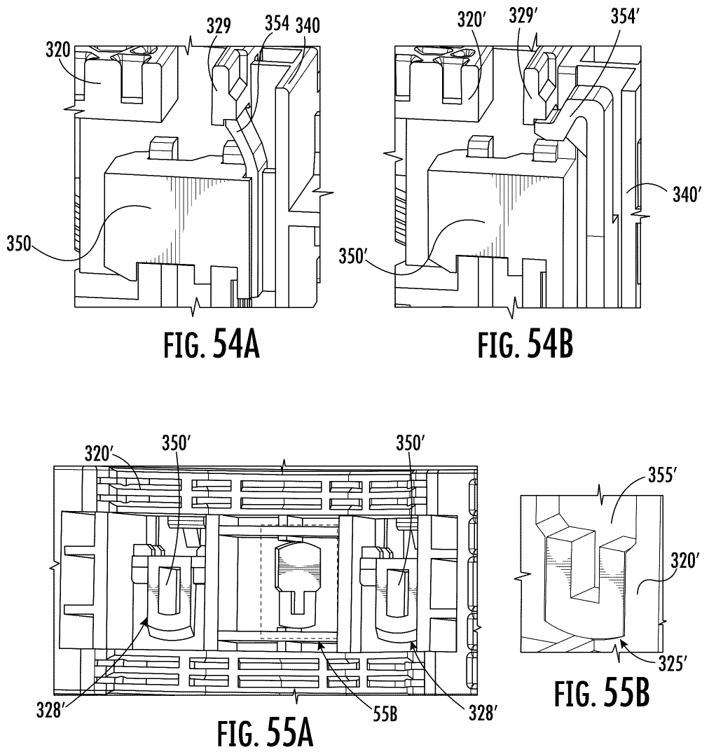

FIGS. 55A-55B illustrate the positioning feature 355′ of the adapter extension 340′ received within the aperture 325′ of the clamp 320′ according to embodiments of the present invention. The positioning feature 365′ of the hanger panel 360′ is configured to engage with the aperture 325′ of the clamp 320′ or aperture 345′ of the adapter extension 340′ in a similar manner.

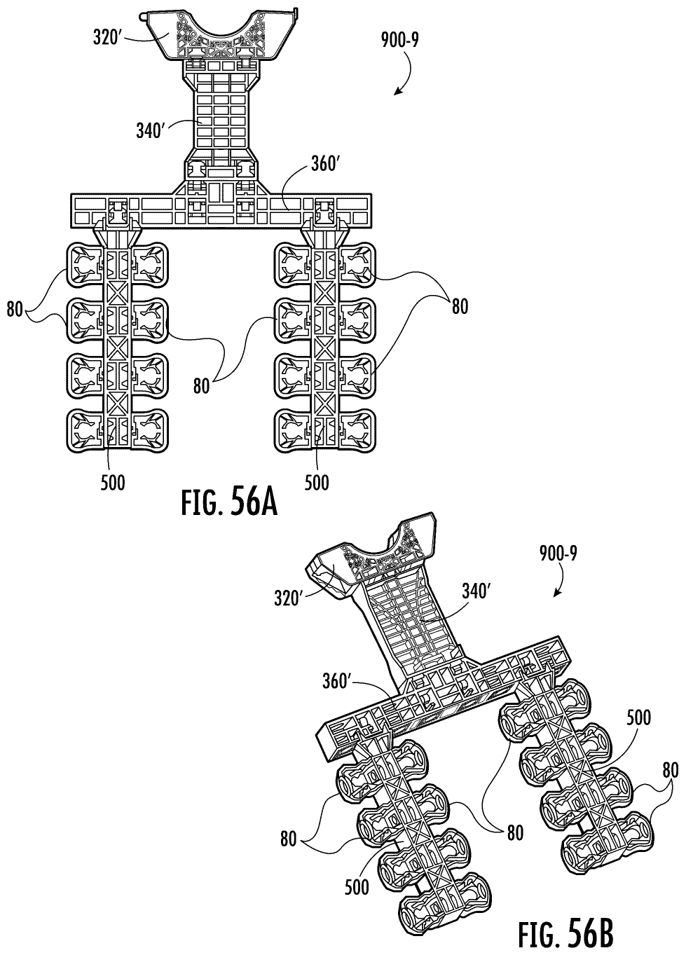

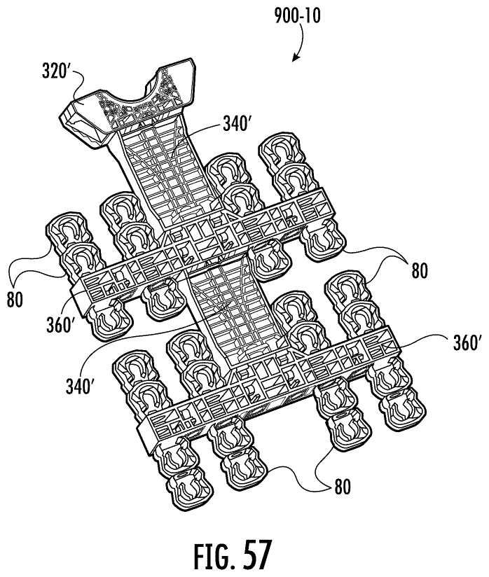

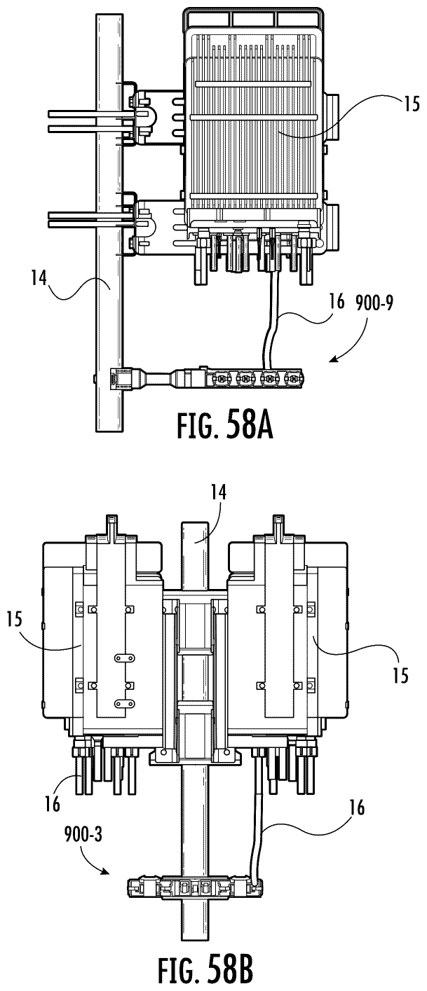

FIGS. 56A-56B illustrate an assembly 900-9 having an exemplary configuration that may be formed utilizing the clamp 320′, adapter extension 340′, hanger panel 360′, and hanger panels 500 described herein. A plurality of cable hangers 80 may be secured to the hanger panels 500. In some embodiments, the assembly 900-9 may be used to organize cables 16 connected to one or more remote radio units 15 (see, e.g., FIGS. 58A-58B). FIG. 57 illustrates an assembly 900-10 having another exemplary configuration. As shown in FIG. 57, two adapter extensions 340′ and hanger panels 360′ are configured in a stacked relationship.

As noted above, and shown in FIGS. 58A-58B, in addition to antennas, in some embodiments, the components described herein may be used for organizing and/or managing cables 16 from one or more remote radio units 15.

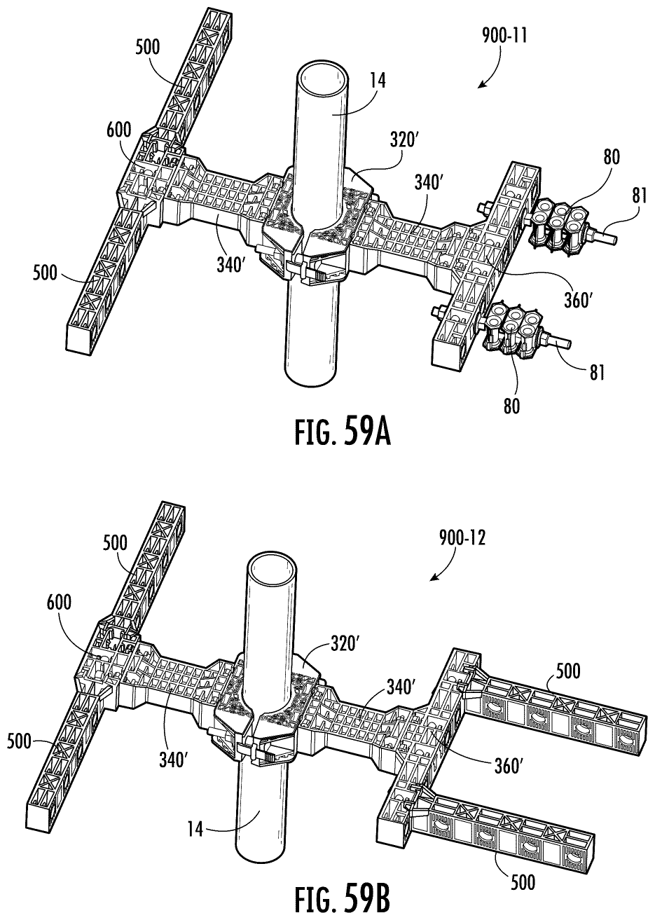

Referring to FIGS. 59A-59B, alternative assemblies 900-11, 900-12 according to embodiments of the present invention are illustrated. These assemblies 900-11, 900-12 have additional exemplary configurations that may be formed utilizing components described herein and may be used for organizing and/or managing cables 16 from one or more remote radio units 15. As shown in FIG. 59A, in some embodiments, the assembly 900-11 may include the clamp 320′ secured to a mounting pole 14. Two adapter extensions 340′ are engaged with the clamp 320′ and extend outwardly in opposing directions. Two hanger panels 500 are engaged with an adapter extension 600 which is engaged with one of the adapter extensions 340′. The two hanger panels 500 extend outwardly in opposing directions from the adapter extension 600 and are positioned generally perpendicular to the adapter extension 340′. A hanger panel 360′ is engaged with the other adapter extension 340′ and a plurality of cable hangers 80 are coupled to the hanger panel 360′ with respective fasteners 81.

As shown in FIG. 59B, in some embodiments, the assembly 900-12 may include the clamp 320′ to a mounting pole 14. Two adapter extensions 340′ are engaged with the clamp 320′ and extend outwardly in opposing directions. Two hanger panels 500 are engaged with an adapter extension 600 which is engaged with one of the adapter extensions 340′. The two hanger panels 500 extend outwardly in opposing directions from the adapter extension 600 and are positioned generally perpendicular to the adapter extension 340′. A hanger panel 360′ is engaged with the other adapter extension 340′. Two hanger panels 500 are engaged with the hanger panel 360′ and extend outwardly therefrom. The two hanger panels 500 are positioned generally perpendicularly to hanger panel 360′.

It should also be apparent that any of the assemblies 110, 210, 310, 410 may be provided as a kit, which may include the clamp and one or more of the mounting adapter, the hanger panel(s), and the adapter extension.

It will also be apparent to those of skill in this art that other configurations of securing features for securing the clamps to a mounting pole or other mounting structure beyond those shown herein may be employed. One clamp should have a first securing feature (exemplified, but not limited to, the latch 30, the clamp pin 170, the latch 280, and the carriage bolt 390) and the other clamp should have a second securing feature (exemplified, but not limited to, the fingers 32, the eye bolt 176, the flanges 231, and a nut for the carriage bolt 390) that engages the first securing feature to maintain the clamps in a secured condition. Other potential features include latches, flanges, fingers and the like of different configurations, tongue-in-groove configurations, sliding rails and channels, and the like. It may be desirable with any of these configurations that the securing features be configured so that the clamps may be secured on mounting poles of different diameters.

The foregoing is illustrative of the present invention and is not to be construed as limiting thereof. Although exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The invention is defined by the following claims, with equivalents of the claims to be included therein.

What is claimed is:

1. An assembly for providing mounting locations for cable hangers for an antenna, the assembly comprising:
a hanger panel having a generally rectangular skeletal base, the hanger panel comprising a plurality of mounting holes spaced apart on opposing side surfaces along a length of the base and at least one securing mechanism coupled to and extending outwardly from an end of the base, and
an adapter extension having a side wall comprising a recess,
wherein the hanger panel is secured to the side wall of the adapter extension by the at least one securing mechanism received within the recess.

2. The assembly according to claim 1, wherein at least one of the hanger panel and the adapter extension are formed of a polymeric material.

3. The assembly according to claim 1, wherein the base of the hanger panel comprises a plurality of support beams include axial beams and/or cross beams.

4. The assembly according to claim 1, wherein each of the plurality of mounting holes have a nominal diameter of ¾ inch.

5. The assembly according to claim 1, wherein the at least one securing mechanism includes a latch sized and configured to fit within the recess of the adapter extension.

6. The assembly according to claim 5, wherein the latch comprises a plurality of wings extending outwardly therefrom and a lower lip extending downwardly therefrom.

7. The assembly according to claim 1, wherein the at least one securing mechanism includes a pair of hooks extending from the end of the base, the pair of hooks configured to engage a top edge of the adapter extension.

8. The assembly according to claim 1, wherein the adapter extension has a generally rectangular skeletal base having four side walls, wherein at least two of the side walls comprise a recess configured to receive the at least one securing mechanism of the hanger panel.

9. The assembly according to claim 5, wherein the recess of the adapter extension comprises an open end and a vertical section, and wherein the latch of the hanger panel is configured to be received by the open end and slide down the vertical section.

10. The assembly according to claim 1, wherein the adapter extension further comprises a securing mechanism residing within the recess configured to engage the at least one securing mechanism of the hanger panel.

11. The assembly according to claim 1, wherein the adapter extension is a first adapter extension, and wherein the adapter extension further comprises a pair of latches extending outwardly from a side wall, each latch configured to be received by an opening of a clamp or an opening of a second adapter extension.

12. The assembly according to claim 11, wherein the first adapter extension comprises a second securing mechanism residing above each latch, the securing mechanisms configured to secure the latch within a respective opening of the claim or second adapter extension.

13. A cable hanger assembly, the assembly comprising:
a generally rectangular skeletal base having a length and a width,
a plurality of mounting holes spaced apart on opposing side surfaces along the length of the base;
a latch coupled to and extending outwardly from an end of the base; and
a pair of hooks extending outwardly from the end of the base above the latch,
wherein the cable hanger assembly is formed of a polymeric material.

14. The assembly according to claim 13, wherein the base comprises a plurality of support beams include axial beams and/or cross beams.

15. The assembly according to claim 13, wherein each of the plurality of mounting holes have a nominal diameter of ¾ inch.

16. The assembly according to claim 13, wherein the latch is sized and configured to fit within a recess of an adapter extension.

17. The assembly according to claim 13, wherein the latch comprises a plurality of wings extending outwardly therefrom and a lower lip extending downwardly therefrom.

18. The assembly according to claim 13, wherein the pair of hooks is configured to engage a top edge of an adapter extension.

19. A cable mounting kit, the kit comprising
first and second clamps, the first clamp including a first securing feature configured to engage a second securing feature on the second clamp to enable the first and second clamps to enclose and mount on a mounting structure, each of the first and second clamps including a clamping surface configured to engage the mounting structure and an opposed outer surface with a pair of first mounting openings; and
a cable hanger mounting assembly, the cable hanger mounting assembly comprising:
a hanger panel having a generally rectangular skeletal base, the hanger panel comprising a plurality of mounting holes spaced apart on opposing side surfaces along a length of the base and at least one securing mechanism coupled to and extending outwardly from an end of the base, and
an adapter extension having a first side wall comprising a recess and a second side wall comprising a pair of latches,
wherein the at least one securing mechanism of the hanger panel is configured to be received within the recess of the adapter extension, and
wherein the pair of latches of the adapter extension is configured to be received by the pair of first mounting openings of the first and second clamps.

20. The kit according to claim 19, wherein the adapter extension is a first adapter extension, the kit further comprising a second adapter extension, the second adapter extension comprising a base having second pair of latches being receivable within the first mounting openings of the first and second clamps, a member extending from the base, and a head with a pair of second mounting openings, the pair of latches of the first adapter extension configured to be received by the pair of second mounting openings.
